(19) United States
(12) Patent Application Publication
(10) Pub. No.: US 2024/0384639 A1
(43) Pub. Date: Nov. 21, 2024

(54) Distributed Network Optimization for Large-Scale Production Network Models

(71) Applicant: XECTA INTELLIGENT PRODUCTION SERVICES, Houston, TX (US)

(72) Inventors: Sathish Sankaran, Spring, TX (US); Zhenyu Guo, Houston, TX (US); Masahiro Nagao, College Station, TX (US)

(21) Appl. No.: 18/666,509

(22) Filed: May 16, 2024

Related U.S. Application Data
(60) Provisional application No. 63/502,984, filed on May 18, 2023.

(51) Int. Cl. E21B 43/30; E21B 43/38; G06F 30/28; G06Q 50/02

(52) U.S. Cl. CPC E21B 43/30; E21B 43/38; G06F 30/28; G06Q 50/02

(57) ABSTRACT

A method of modeling pressure and flux within an integrated network of multiple wells, including: measuring reservoir pressures at each well; measuring a separator pressure at the separator; receiving or generating a model of the integrated network, the model including a node representing the separator, at least one node representing each well, and pressure constraints at the separator and each well; dividing the model into a plurality of subnetworks; performing an alternating direction method of multipliers (ADMM) optimization by iteratively solving a plurality of optimization equations each corresponding to a different subnetwork; determining a pressure at each node and a flux between each of the nodes in the model based on the optimization; and producing fluids from the network of multiple wells based on the determined pressures and fluxes in the model.

### CROSS-REFERENCE TO RELATED APPLICATION

This application claims priority to U.S. Provisional Application No. 63/502,984 filed May 18, 2023, entitled “DISTRIBUTED NETWORK OPTIMIZATION FOR LARGE-SCALE PRODUCTION NETWORK MODELS” by Sathish Sankaran, Zhenyu Guo, and Masahiro Nagao, which is incorporated herein by reference as if reproduced in its entirety.

### TECHNICAL FIELD

This invention relates to modeling integrated production (e.g., well and pipeline) networks and, more particularly, to methods for modeling pressure and flux within an integrated network of multiple wells, each extending into a subterranean reservoir and being fluidly connected to the same separator.

### BACKGROUND

Understanding well production performance in hydrocarbon reservoirs in a timely manner is essential for optimizing reservoir management, improving operational efficiency, and maximizing asset value for producers and operators. As operations extend to more complex reservoirs for a large-scale surface network, the industry is faced with challenges to assess and develop these fields effectively. Early understanding of reservoir performance and mitigating remaining uncertainties are important to earning the maximum possible benefit from the assets. Optimization of production networks is key for managing efficient hydrocarbon production as part of closed-loop asset management. Large-scale surface network optimization is a challenging task that involves high nonlinearity with numerous constraints. Traditional approaches may include a network simulator based on sequential programming to solve the non-linear large-scale surface network optimization. In particular, the network simulator may be configured to use an optimizer to ensure that optimal management of a coupled surface and production system is achieved. For example, the network simulator may be used to achieve optimum oil production by adjusting one or more parameters, such as pressure drops across the flow lines and surface facilities, the interaction among a plurality of wells in the production network, and the boundary conditions, etc., in the surface network for different optimization scenarios. However, the computational cost of solving the surface network optimization may exponentially increase with the size and complexities of the surface network. In some embodiments, for oil and gas fields, optimization of production operations may be a major factor in increasing hydrocarbon production and reducing production costs for a surface network. Production systems are often constrained by reservoir conditions, deliverability of the pipeline network, fluid handling capacity of surface facilities, and other safety and economic considerations. Often, the design of the surface or subsea pipeline network should be tightly integrated as part of the field development design to account for expected reservoir life variations in fluids produced or injected. Once installed, the objective of dynamic production optimization is to find the best operational settings for the integrated network (comprising the reservoir, wellbore, pipelines, chokes, compressors, pumps, and the facility) at any given time, subject to all constraints, to achieve certain operational goals.

In some embodiments, integrated network optimization is computationally difficult and time-consuming to solve a large-scale nonlinear surface network optimization problem. Studies have been conducted to address various aspects of production operation problems. These studies, for example, include a linear programming method used to optimize a long-term field development plan for a specified multi-reservoir pipeline system, optimization of lift-gas allocation to maximize field oil production, and an optimization technique for allocating both production rates and lift-gas rate to wells subject to multiple flux and pressure constraints. Traditional methods rely on sequential programming (SQP or SLP) to simplify the overarching nonlinear, non-convex, and mixed integer problems, which are typically difficult to solve. As a result, the computational cost of the traditional methods may exponentially increase with the size and complexities of the production network system. To conduct optimized operations in a timely manner, an efficient production optimization algorithm is needed for large-scale network systems.

In some embodiments, distributed agent-based optimization methods are gaining attention as a robust approach for large dataset problems that involve numerous decision variables and constraints in statistics and machine learning. A large-scale network optimization problem may be decomposed into subnetwork problems and solved in a distributed and parallelized fashion, thus providing improvements in computational efficiency with parallel runs. Various types of distributed optimization algorithms have been applied to different applications, including analytical target cascading (ATC), alternating direction method of multipliers (ADMM), proximal message passing, auxiliary problem principle (APP).

The ADMM algorithm is a distributed agent optimization algorithm based on an augmented Lagrangian scheme. The ADMM algorithm may be used to determine partial updates for dual variables to solve a structured convex quadratic programming (QP) problem, such as statistics, compressive sensing, image processing, medical imaging, remote sensing, image compression, machine learning, distributed optimization, regularized estimation, and semi-definite programming, optimal power flow, etc. The ADMM algorithm may be used to perform a plurality of iterations of alternating steps of updates on subsets of the variables of the surface network. For each iteration, the ADMM algorithm may be used to alternately solve for a first variable while holding a second fixed, and solving for the second variable while holding the first variable fixed. For example, since the power flow network system involves millions of nodes and links with numerous constraints, the ADMM algorithm is well-suited as an efficient distributed agent optimization method. The ADMM algorithm may handle a large dataset in a distributed fashion, where it is not required to exchange or gather information in one place from different agents. Thus, the ADMM algorithm may be used to efficiently solve the nonlinear surface network, which includes a plurality of constrained dynamical systems formulated from system dynamics, constraints, and a user-specified cost function. In some embodiments,

It is now recognized that a need exists for more computationally efficient methods that can accelerate the large-scale surface network optimization of integrated production networks.

### BRIEF DESCRIPTION OF THE DRAWINGS

FIG. 1 illustrates a schematic representation of a hierarchical network system, in accordance with certain embodiments.

FIG. 2 illustrates a schematic representation of a simple network system for ADMM optimization, in accordance with certain embodiments.

FIG. 3 illustrates a schematic representation of subnetworks for ADMM optimization, in accordance with certain embodiments.

FIG. 4 illustrates a flow chart demonstrating steps for network simulation, in accordance with certain embodiments.

FIG. 5 illustrates a schematic representation of a simple network system for ADMM optimization with choke size and its subnetworks on the right hand side, in accordance with certain embodiments.

FIG. 6 illustrates a flow chart demonstrating the ADMM steps for network optimization with choke, in accordance with certain embodiments.

FIG. 7 illustrates a schematic representation of a machine learning based proxy model for multiphase flow correlation, in accordance with certain embodiments.

FIGS. 8A-8E illustrate a set of plots showing training and blind test for the calculation of multiphase flow correlation, in accordance with certain embodiments.

FIG. 9 illustrates a schematic representation of modeling approaches for reservoir connectivity identification and production forecasting, in accordance with certain embodiments.

FIG. 10 illustrates a schematic representation of a network system for the application of ADMM simulation, in accordance with certain embodiments.

FIGS. 11A-11C illustrate plots comparing pressure and multiphase flux between ADMM and reference simulator for a six-well case, in accordance with certain embodiments.

FIGS. 12A and 12B illustrate plots of calculated pressure and multiphase flux from ADMM and reference simulator for a 256-well case, in accordance with certain embodiments.

FIGS. 13A-13D illustrate plots comparing pressure and multiphase flux between ADMM and reference simulator for the 256-well case, in accordance with certain embodiments.

FIGS. 14A and 14B illustrate plots of calculated pressure and multiphase flux from ADMM and reference simulator optimization for a nine-well case, in accordance with certain embodiments.

FIGS. 15A-15D illustrate plots comparing pressure and multiphase flux between ADMM and reference simulator optimization for the nine-well case, in accordance with certain embodiments.

FIG. 16 illustrates a plot comparing optimized choke pressure drop between ADMM and reference simulator optimization for a 256-well case, in accordance with certain embodiments.

FIGS. 17A and 17B illustrate plots of calculated pressure and multiphase flux from ADMM and reference simulator optimization for the 256-well case, in accordance with certain embodiments.

FIGS. 18A-18D illustrate plots comparing pressure and multiphase flux between ADMM and reference simulator optimization for the 256-well case, in accordance with certain embodiments.

FIG. 19 illustrates a plot comparing optimized choke pressure drop between ADMM and reference simulator optimization for a 1024-well case, in accordance with certain embodiments.

FIGS. 20A and 20B illustrate plots of calculated pressure and multiphase flux from ADMM and reference simulator optimization for the 1024-well case, in accordance with certain embodiments.

FIGS. 21A-21D illustrate plots comparing pressure and multiphase flux between ADMM and reference simulator optimization for the 1024-well case, in accordance with certain embodiments.

FIG. 22 illustrates a plot comparing the computational time between the reference simulator and ADMM for different sizes of the networks in accordance with certain embodiments.

FIG. 23 illustrates a schematic representation of a production network in a field case, in accordance with certain embodiments.

FIGS. 24A and 24B illustrate plots of calculated pressure and multiphase flux from ADMM and reference simulator for the field case, in accordance with certain embodiments.

FIGS. 25A-25D illustrate plots comparing pressure and multiphase flux between ADMM and reference simulator for the field case, in accordance with certain embodiments.

FIG. 26 illustrates a flow chart of an example method of modeling pressure and flux within an integrated network of multiple wells, in accordance with certain embodiments.

FIG. 27 illustrates a flow chart of an example method of modeling pressure and flux to perform a choke optimization in an integrated network of multiple wells, in accordance with certain embodiments.

FIG. 28 illustrates a flow chart of an example method of modeling pressure and flux within an integrated network of multiple wells using a proxy model, in accordance with certain embodiments.

FIG. 29 illustrates a block diagram showing an example information handling system in accordance with certain embodiments of the present disclosure, in accordance with certain embodiments.

While embodiments of this disclosure have been depicted and described and are defined by reference to exemplary embodiments of the disclosure, such references do not imply a limitation on the disclosure, and no such limitation is to be inferred. The subject matter disclosed is capable of considerable modification, alteration, and equivalents in form and function, as will occur to those skilled in the pertinent art and having the benefit of this disclosure. The depicted and described embodiments of this disclosure are examples only, and not exhaustive of the scope of the disclosure.

### DETAILED DESCRIPTION

Illustrative embodiments of the present disclosure are described in detail herein. In the interest of clarity, not all features of an actual implementation may be described in this specification. It will of course be appreciated that in the development of any such actual embodiment, numerous implementation-specific decisions may be made to achieve the specific implementation goals, which may vary from one implementation to another. Moreover, it will be appreciated that such a development effort might be complex and time-consuming, but would nevertheless be a routine undertaking for those of ordinary skill in the art having the benefit of the present disclosure.

The presently disclosed methods apply one or more ADMM frameworks to solve a large-scale network optimization problem for a large-scale network system with a plurality of wells and interconnecting pipelines. In the one or more ADMM frameworks, the large-scale network system is broken down into a plurality of small sub-network systems. Then, a smaller optimization problem is formulated for each of the plurality of small sub-networks. Thus, the large-scale network optimization may be divided into a plurality of sub-network optimization problems which may be solved in parallel using multiple computer cores so that the entire system optimization will be accelerated. A large-scale surface network involves many inequality and equality constraints, which are effectively handled by using augmented Lagrangian method to enhance the robustness of convergence quality. Additionally, proxy or hybrid models can also be used for pipe flow and pressure calculation for every network segment to further speed up the optimization.

The disclosed ADMM optimization methods may be validated by several synthetic cases. First, the disclosed ADMM optimization methods may be applied to surface network simulation problems of various sizes and complexities (configurations, fluid types, pressure regimes, etc.), where the pressure for all nodes and fluxes in all links will be calculated with a specified separator pressure and reservoir pressures. High accuracy may be obtained from the one or more ADMM frameworks compared with a traditional simulator. Next, the disclosed ADMM optimization methods may be applied to network optimization problems and used to optimize the pressure drop across a surface choke for every well to maximize oil production. In a large-scale network case with over 1000 wells, the disclosed ADMM optimization methods using the one or more ADMM frameworks may yield 2×-3× speedups in computation time with reasonable accuracy compared with benchmarks. Finally, the proposed ADMM optimization methods may be applied to a field case, validating that the one or more ADMM frameworks may properly work for the actual field applications.

The present disclosure relates to methods for modeling pressure and flux within an integrated production network using the one or more ADMM frameworks for surface network optimization which is developed using the distributed agent optimization algorithm. The proposed ADMM frameworks provide superior computational efficiency for large-scale network optimization problems compared with existing benchmark methods. It enables more efficient and frequent decision-making of large-scale petroleum field management to maximize hydrocarbon production subject to numerous system constraints.

More specifically, the present disclosure provides a method of modeling pressure and flux within an integrated network of multiple wells, the multiple wells each extending into a subterranean reservoir and being fluidly connected to the same separator, the method comprising: measuring reservoir pressures at each well of the multiple wells; measuring a separator pressure at the separator; receiving or generating a model of the integrated network, the model including a node representing the separator, at least one node representing each well of the multiple wells, and pressure constraints at the separator and each well based on the measured separator pressure and reservoir pressures; dividing the model of the integrated network into a plurality of subnetworks; performing an alternating direction method of multipliers (ADMM) optimization by iteratively solving a plurality of optimization equations, each optimization equation corresponding to a different subnetwork of the plurality of subnetworks; determining a pressure at each node and a flux between each of the nodes in the model based on the optimization; and producing fluids from the network of multiple wells based, at least in part, on the determined pressures and fluxes in the model.

In addition, the present disclosure provides a method of modeling pressure and flux within an integrated network of multiple wells, the multiple wells each extending into a subterranean reservoir and being fluidly connected to the same separator, the method comprising: measuring reservoir pressures at each well of the multiple wells; measuring a separator pressure at the separator; receiving or generating a model of the integrated network, the model including a node representing the separator, at least one node representing each well of the multiple wells, a representative choke at each well of the multiple wells, and pressure constraints at the separator and each well based on the measured separator pressure and reservoir pressures; dividing the model of the integrated network into a plurality of subnetworks; performing an alternating direction method of multipliers (ADMM) optimization by iteratively solving a plurality of optimization equations, each optimization equation corresponding to a different subnetwork of the plurality of subnetworks; determining an optimized pressure drop across each representative choke in the model based on the optimization; and adjusting a size, position, or presence of one or more chokes in the network of multiple wells based, at least in part, on the optimized pressure drops.

In addition, the present disclosure provides a method of modeling pressure and flux within an integrated network of multiple wells, the multiple wells each extending into a subterranean reservoir and being fluidly connected to the same separator, the method comprising: measuring reservoir pressures at each well of the multiple wells; measuring a separator pressure at the separator; receiving or generating a model of the integrated network, the model including a node representing the separator, at least one node representing each well of the multiple wells, and pressure constraints at the separator and each well based on the measured separator pressure and reservoir pressures; determining an initial pressure value at each node and an initial flux value along each link between consecutive nodes in the model; training a machine learning algorithm based on the initial pressure and flux values; generating a proxy model that correlates multiphase flow along a link with pressure values using the machine learning algorithm; dividing the model of the integrated network into a plurality of subnetworks; performing an alternating direction method of multipliers (ADMM) optimization by iteratively solving a plurality of optimization equations, each optimization equation corresponding to a different subnetwork of the plurality of subnetworks and incorporating the proxy model; determining a pressure at each node and a flux between each of the nodes in the model based on the optimization; and producing fluids from the network of multiple wells based, at least in part, on the determined pressures and fluxes in the model.

The disclosed methods use the ADMM algorithm for large-scale production system optimization problems. The ADMM is well suited for distributed convex optimization and, in particular, for large-scale problems arising in statistics, machine learning, and related areas. The disclosed methods were developed as a new integrated production operation optimization algorithm using ADMM for large-scale network systems that satisfy physics and numerous constraints. By using parallelization, ADMM can provide superior computational efficiency compared with incumbent optimization approaches for large-scale network problems.

In some embodiments, the disclosed ADMM optimization methods may allow using one or more ADMM frameworks for network simulation to solve for pressure and flux of all nodes and links, and network optimization in which the additional choke pressure drops at wellheads are optimized to maximize the oil production rate of the gathering system. Furthermore, the disclosed ADMM optimization methods may accelerate large-scale gathering system optimization by solving the large network system in a distributed fashion. Additionally, the disclosed ADMM optimization methods may apply an augmented Lagrangian scheme to effectively deal with a significant amount of inequality constraints, so that the large-scale network optimization can be accelerated further compared with benchmarks.

### Hierarchical Network System

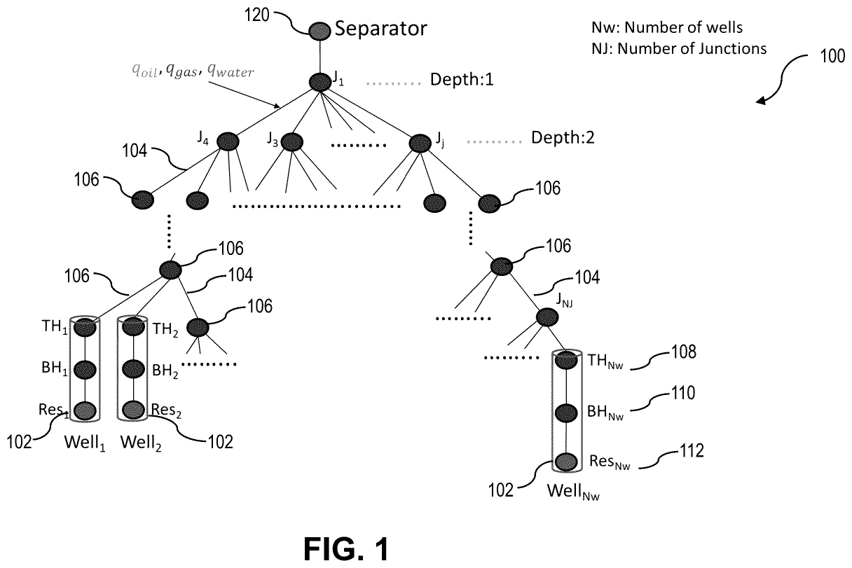

FIG. 1 illustrates a schematic representation of a hierarchical network system 100, in accordance with certain embodiments. In some embodiments, the hierarchical network system 100 includes a gathering system having a plurality of production components, such as reservoir, wellbore, pipelines, chokes, compressors, pumps, and the facility. For example, the hierarchical network system 100 is modeled as a tree-like hierarchical network without loops, which includes a plurality of wells 102, links 104, and nodes 106. Each of wells 102 may include three nodes, such as a tubing head (TH) node 108, a bottom hole (BH) node 110, and a reservoir node 112. In some embodiments, the hierarchical network system 100 may include multiple downhole completions, multi-laterals, and other complex well configurations. Each of links 104 may include a device which has a pressure drop, such as a tubing string, surface pipeline, or a choke. Each of nodes 106 may include a junction or terminal point to a respective link. In some embodiments, the hierarchical network system 100 includes one separator 120, which is connected to all reservoir nodes 112 through the plurality of wells 102, links 104, and nodes 106 in the tree-like hierarchical network. In some embodiments, the hierarchical network system 100 may be used to determine a model by estimating the pressure of the plurality of nodes 106 and multiphase flux at the plurality of links 104. Likewise, the hierarchical network system 100 may include a plurality of separator nodes 120 associated with multiple hierarchical networks with no flow splitting or loops, and for injection systems where the flow direction is reversed.

In some embodiments, the multiphase flow in the hierarchical network system 100 may be described as a black oil fluid model. The pressure drop across tubing or pipeline is calculated by multiphase empirical flow correlations. In some embodiment, a modified Hagedorn and Brown method may be used for the calculation of the pressure drop at near vertical tubing strings. In some embodiments, a Beggs and Brill method may be used for near horizontal surface pipelines. A multiphase inflow performance relationship (IPR) and a deliverability equation based on tuning parameters (c and n) for gas reservoirs may be used for the calculation of well inflow performance. In some embodiments, the choice of correlations is based on standard nodal analysis practices and a selected fluid model, such as a black oil fluid model or a compositional fluid model.

In some embodiments, for the hierarchical network system 100, the objective of the optimization problem may be formulated to maximize oil production by changing choke size. For example, a choke pressure drop may be used as the decision variable to maximize oil production under a steady-state condition. In the steady-state condition, all reservoir node pressure and separator node pressure are given as boundary conditions. In some embodiments, other objective functions and constraints may be considered without loss of generality. In addition, other decision variables such as artificial lift parameters (e.g., gas lift injection rate, ESP frequency, etc.) may also be included in the hierarchical network system 100.

### Alternating Direction Method of Multipliers (ADMM)

In some embodiments, the ADMM optimization method attempts to solve a distributed convex optimization problem in a distributed manner by decomposing the problem into a plurality of subproblems. Thus, the ADMM optimization methods may blend the decomposability of dual ascent with the superior convergence properties of the method of multipliers. In distributed agent optimization, the ADMM optimization methods may take the form of a decomposition-coordination procedure, where the solutions to small local subproblems are coordinated to find a solution to a large global problem. The ADMM optimization methods may blend the benefits of dual decomposition and augmented Lagrangian methods for constrained optimization. The algorithm solves problems in the form of Equation 1.

minimize ƒ(x)+g(z)

subject to Ax+Bz=c (1)

where ƒ(x) and g(x) are convex functions, variables x∈ [symbol] ⁿ, z∈R [symbol] ^{m}, A∈ [symbol] ^{p×n}, B∈ [symbol] ^{p×m}, and c∈ [symbol] ^{p}.

In some embodiments, ƒ(x) and g(x) are convex functions which bend upwards with increasing first derivatives. Thus, the minimization function for the optimization problem may be split into two parts, ƒ(x) and g(z). Therefore, the objective function of the optimization problem is also separable across this splitting. As in the method of multipliers, an augmented Lagrangian (objective function) is formed as follows:

$${L}_{ρ} ( x , z , y ) = f ( x ) + g ( z ) + {y}^{T} ( A x + B z - c ) + \frac{ρ}{2} {‖ Ax + Bz - c ‖}_{2}^{2} \qquad ( 2 )$$

Where ƒ(x) and g(x) are convex functions, y is the dual variable (Lagrange multiplier), ρ is a penalty parameter (ρ>0), and variables x∈ [symbol] ⁿ, z∈ [symbol] ^{m}, A∈ [symbol] ^{p×m}, B∈ [symbol] ^{p×m}, and c∈ [symbol] ^{p}.

In some embodiments, the ADMM optimization methods may apply dual ascent and the method of multipliers to solve the minimization function for the optimization problem in a plurality of iterations. The ADMM iterations consist of three steps: x-minimization, z-minimization, and a dual variable update. In this way, x and z are updated in an alternating or sequential fashion. Because the x-minimization step and z-minimization step are separable, the x-minimization step and z-minimization step may be run in parallel to speed up the ADMM iterations. ADMM consists of the following iterations:

$${x}^{k + 1} = arg min [ {L}_{ρ} ( x , {z}^{k} , {y}^{k} ) ] \qquad ( 3 )$$

$${z}^{k + 1} = arg min [ {L}_{ρ} ( {x}^{k + 1} , z , {y}^{k} ) ]$$

$${y}^{k + 1} = {y}^{k} + ρ ( {Ax}^{k + 1} + {Bz}^{k + 1} - c )$$

where k is the iteration index.

In some embodiments, the ADMM optimization methods may be applied to decompose a large-scale network into a plurality of local subnetworks and solve a plurality of subnetwork optimization subproblems associated with the plurality of local subnetworks separately. Therefore, the ADMM steps may be run in parallel for the plurality of subnetwork optimization subproblems to speed up the optimization. Additionally, the equality and inequality constraints are effectively handled by using the augmented Lagrangian scheme. The penalty term in Equation (2) yields convergence without assumptions of strict convexity or finiteness of the function.

In some embodiments, production operations are subject to multiple capacity, safety, and economic constraints. Thus, there are usually a significant number of constraints in a large-scale gathering system. For traditional separable programming approaches, such as sequential quadratic programming (SQP) and sequential linear programming (SLP), inequality constraints are treated using an iterative approach called the active set method. Thus, the traditional separable programming approach may be computationally expensive when there are a significant amount of inequality constraints.

### ADMM for Network Optimization

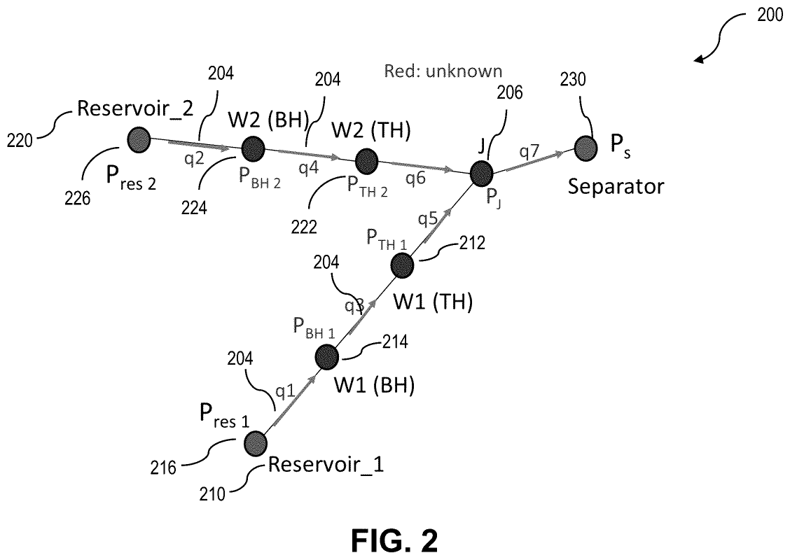

FIG. 2 illustrates a schematic representation of a simple network system 200 for ADMM optimization, in accordance with certain embodiments. The simple network system 200 includes two wells 210 and 220, and one separator 230. For example, well 210 includes a TH node 212, a BH node 214, and a reservoir node 216. As another example, well 220 includes a TH node 222, a BH node 224, and a reservoir node 226. Wells 210 and 220 are connected to the separator 230 via a plurality of links 204 and a junction node 206. The two reservoir nodes 216 and 226 and the separator node 230 have known pressures as boundary conditions (Pᵣₑₛ₁, Pᵣₑₛ₂, and P_{S}). In the integrated network optimization problem, the objective is to maximize the hydrocarbon production by maintaining one or more constraints and solving for pressure and flux for all nodes and links. For simplicity, the simple network system 200 is configured to implement a network simulation with no optimization variables and fixed choke sizes or choke pressure drops. Without loss of generality, the simple network system 200 may set the fixed choke pressure drop to be zero. In some embodiments, the constrained optimization problem for this system can be written as follows:

$$maximize {q}_{7} ( and calculate node pressure ) \qquad ( 4 )$$

$$Subject to$$

$${q}_{1} ( {P}_{res 1} , {P}_{BH 1} ) = {q}_{3} ( {P}_{PH 1} , {P}_{TH 1} ) = {q}_{5} ( {P}_{TH 1} , {P}_{J} ) ,$$

$${q}_{2} ( {P}_{res 2} , {P}_{BH 2} ) = {q}_{4} ( {P}_{PH 2} , {P}_{TH 2} ) = {q}_{6} ( {P}_{TH 2} , {P}_{J} ) ,$$

$${q}_{5} + {q}_{6} = {q}_{7} ( {P}_{J} , {P}_{S} )$$

where qᵢ is the flux at i th link and Pⱼ is the pressure at node name j.

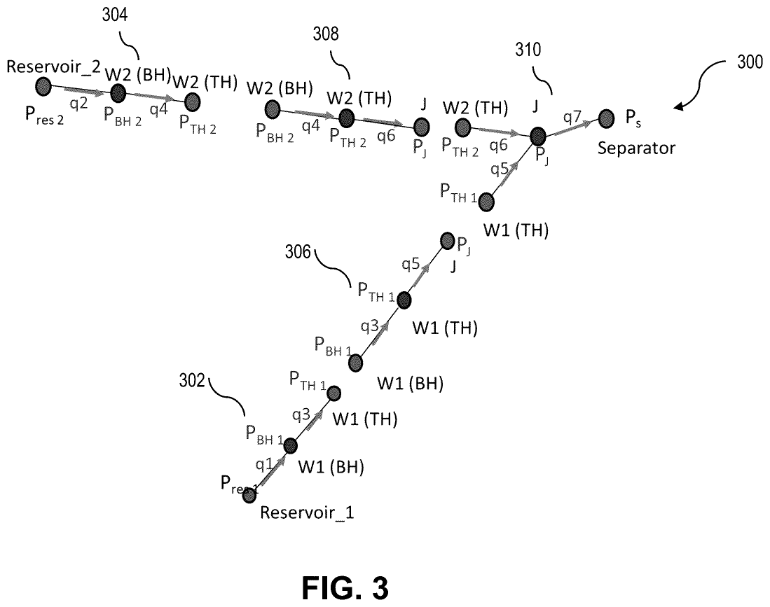

FIG. 3 illustrates a schematic representation 300 of subnetworks for ADMM optimization, in accordance with certain embodiments. The first step in applying ADMM optimization is to breakdown the whole network system into a plurality of small subnetworks. For example, the network of FIG. 2 can be broken down into five subnetworks, such as 302, 304, 306, 308, and 310. By solving for each small subnetwork optimization iteratively, the ADMM optimization methods may obtain the pressure and flux for the entire network system. Local optimization problems can be formulated for the subnetworks as follows:

$$maximize {q}_{1} ( {q}_{1} = {q}_{3} ) \qquad ( 5 )$$

$$subject to {P}_{BH 1} ( {P}_{res 1} , {q}_{1} ) = {P}_{BH 1} ( {P}_{TH 1} , {q}_{1} )$$

$$maximize {q}_{2} ( {q}_{2} = {q}_{4} ) \qquad ( 6 )$$

$$subject to {P}_{BH 2} ( {P}_{res 2} , {q}_{2} ) = {P}_{BH 2} ( {P}_{TH 2} , {q}_{2} )$$

$$maximize {q}_{3} ( {q}_{3} = {q}_{5} ) \qquad ( 7 )$$

$$subject to {P}_{TH 1} ( {P}_{BH 1} , {q}_{3} ) = {P}_{BH 1} ( {P}_{J} , {q}_{3} )$$

$$maximize {q}_{4} ( {q}_{4} = {q}_{6} ) \qquad ( 8 )$$

$$subject to {P}_{TH 2} ( {P}_{BH 2} , {q}_{4} ) = {P}_{TH 2} ( {P}_{J} , {q}_{4} )$$

$$maximize {q}_{5} + {q}_{6} ( {q}_{5} + {q}_{6} = {q}_{7} ) \qquad ( 9 )$$

$$subject to {P}_{J} ( {P}_{TH 1} , {q}_{5} ) = {P}_{J} ( {P}_{TH 2} , {q}_{6} ) = {P}_{J} ( {P}_{s} , {q}_{7} )$$

where P_{BH1}(Pᵣₑₛ₁, q₁) is the pressure at “W1(BH)” calculated from upstream nodes “Reservoir_1” as a function of Pᵣₑₛ₁ and q₁, and P_{BH1}(P_{TH1}, q₁) is the pressure at “W1(BH)” calculated from downstream nodes “W1(TH)” as a function of P_{TH1} and q₁.

In some embodiments, the next step in applying ADMM optimization is to apply the augmented Lagrangian (objective function) to each local optimization problem as follows:

$${L}_{ρ , 1} = - {q}_{1} + {y}_{1} ( {P}_{BH 1} ( {P}_{res 1} , {q}_{1} ) - {P}_{BH 1} ( {P}_{TH 1} , {q}_{1} ) ) + \frac{ρ}{2} {‖ {P}_{BH 1} ( {P}_{res 1} , {q}_{1} ) - {P}_{BH 1} ( {P}_{TH 1} , {q}_{1} ) ‖}_{2}^{2} \qquad ( 10 )$$

$${L}_{ρ , 2} = - {q}_{2} + {y}_{2} ( {P}_{BH 2} ( {P}_{res 2} , {q}_{2} ) - {P}_{BH 2} ( {P}_{TH 2} , {q}_{2} ) ) + \frac{ρ}{2} {‖ {P}_{BH 2} ( {P}_{res 2} , {q}_{2} ) - {P}_{BH 2} ( {P}_{TH 2} , {q}_{2} ) ‖}_{2}^{2} \qquad ( 11 )$$

$${L}_{ρ , 3} = - {q}_{3} + {y}_{3} ( {P}_{TH 1} ( {P}_{BH 1} , {q}_{3} ) - {P}_{TH 1} ( {P}_{J} , {q}_{3} ) ) + \frac{ρ}{2} {‖ {P}_{TH 1} ( {P}_{BH 1} , {q}_{3} ) - {P}_{TH 1} ( {P}_{J} , {q}_{3} ) ‖}_{2}^{2} \qquad ( 12 )$$

$${L}_{ρ , 4} = - {q}_{4} + {y}_{4} ( {P}_{TH 2} ( {P}_{BH 2} , {q}_{4} ) - {P}_{TH 2} ( {P}_{J} , {q}_{4} ) ) + \frac{ρ}{2} {‖ {P}_{TH 2} ( {P}_{BH 2} , {q}_{4} ) - {P}_{TH 2} ( {P}_{J} , {q}_{4} ) ‖}_{2}^{2} \qquad ( 13 )$$

$${L}_{ρ , 5} = - ( {q}_{5} + {q}_{6} ) + {y}_{5} ( {P}_{J} ( {P}_{TH 1} , {q}_{5} ) - {P}_{J} ( {P}_{s} , {q}_{7} ) ) + {y}_{6} ( {P}_{J} ( {P}_{TH 2} , {q}_{6} ) - {P}_{J} ( {P}_{s} , {q}_{7} ) ) + \frac{ρ}{2} ( {‖ {P}_{J} ( {P}_{TH 1} , {q}_{5} ) - {P}_{J} ( {P}_{s} , {q}_{7} ) ‖}_{2}^{2} + {‖ {P}_{J} ( {P}_{TH 2} , {q}_{6} ) - {P}_{J} ( {P}_{s} , {q}_{7} ) ‖}_{2}^{2} ) \qquad ( 14 )$$

where yᵢ is i th dual variable (Lagrange multiplier) for the network system. By using the above augmented Lagrangian, the ADMM iterations are formulated as follows:

$$( {q}_{1}^{k + 1} , {P}_{BH 1}^{k + 1} ) = arg min [ {L}_{ρ , 1} ( {P}_{BH 1} , {P}_{res 1}^{bc} , {P}_{TH 1}^{k} , {y}_{1}^{k} ) ] \qquad ( 15 )$$

$${y}_{1}^{k + 1} = {y}_{1}^{k} + ρ ( {P}_{BH 1}^{k + 1} ( {P}_{res 1}^{bc} , {q}_{1}^{k + 1} ) - {P}_{BH 1}^{k + 1} ( {P}_{TH 1}^{k} , {q}_{1}^{k + 1} ) )$$

$$( {q}_{2}^{k + 1} , {P}_{BH 2}^{k + 1} ) = arg min [ {L}_{ρ , 2} ( {P}_{BH 2} , {P}_{res 2}^{bc} , {P}_{TH 2}^{k} , {y}_{2}^{k} ) ] \qquad ( 16 )$$

$${y}_{2}^{k + 1} = {y}_{2}^{k} + ρ ( {P}_{BH 2}^{k + 1} ( {P}_{res 2}^{bc} , {q}_{2}^{k + 1} ) - {P}_{BH 2}^{k + 1} ( {P}_{TH 2}^{k} , {q}_{2}^{k + 1} ) )$$

$$( {q}_{3}^{k + 1} , {P}_{TH 1}^{k + 1} ) = arg min [ {L}_{ρ , 3} ( {P}_{TH 1} , {P}_{BH 1}^{k + I} , {P}_{J}^{k} , {y}_{3}^{k} ) ] \qquad ( 17 )$$

$${y}_{3}^{k + 1} = {y}_{3}^{k} + ρ ( {P}_{TH 1}^{k + 1} ( {P}_{BH 1}^{k + I} , {q}_{3}^{k + 1} ) - {P}_{TH 1}^{k + 1} ( {P}_{J} , {q}_{3}^{k + 1} ) )$$

$$( {q}_{4}^{k + I} , {P}_{T H 2}^{k + 1} ) = [ {L}_{ρ , 4} ( {P}_{T H 2} , {P}_{B H 2}^{k + I} , {P}_{J}^{k} , {y}_{4}^{k} ) ] \qquad ( 18 )$$

$${y}_{4}^{k + 1} = {y}_{4}^{k} + ρ ( {P}_{TH 2}^{k + 1} ( {P}_{BH 2}^{k + I} , {q}_{4}^{k + 1} ) - {P}_{TH 2}^{k + 1} ( {P}_{J} , {q}_{4}^{k + 1} ) )$$

$$( {q}_{5}^{k + 1} , {q}_{6}^{k + 1} , {P}_{J}^{k + 1} ) = arg min [ {L}_{ρ , 5} ( {P}_{J} , {P}_{TH 1}^{k + 1} , {P}_{TH 2}^{k + 1} , {P}_{S}^{bc} , {y}_{5}^{k} , {y}_{6}^{k} ) ] \qquad ( 19 )$$

$${y}_{5}^{k + 1} = {y}_{5}^{k} + ρ ( {P}_{J}^{k + 1} ( {P}_{TH 1}^{k + 1} , {q}_{5}^{k + 1} ) - {P}_{J}^{k + 1} ( {P}_{S}^{bc} , {q}_{7}^{k + 1} ) )$$

$${y}_{6}^{k + 1} = {y}_{6}^{k} + ρ ( {P}_{J}^{k + 1} ( {P}_{TH 2}^{k + 1} , {q}_{6}^{k + 1} ) - {P}_{J}^{k + 1} ( {P}_{S}^{bc} , {q}_{7}^{k + 1} ) )$$

In some embodiments, in the above ADMM iterations (Equations (15)-(19)), the decision variables are taken as liquid flux, and the middle node pressure may be estimated after optimizing the flux. For example, in Equation (15), q₁ is optimized as a decision variable. Once q₁ is determined, the middle node pressure P_{BH1} may be calculated based on the given boundary node pressure values and the calibrated flux. Iterating the above ADMM steps of Equations (15)-(19) may maximize the production of the entire system and solve for node pressure and link flux.

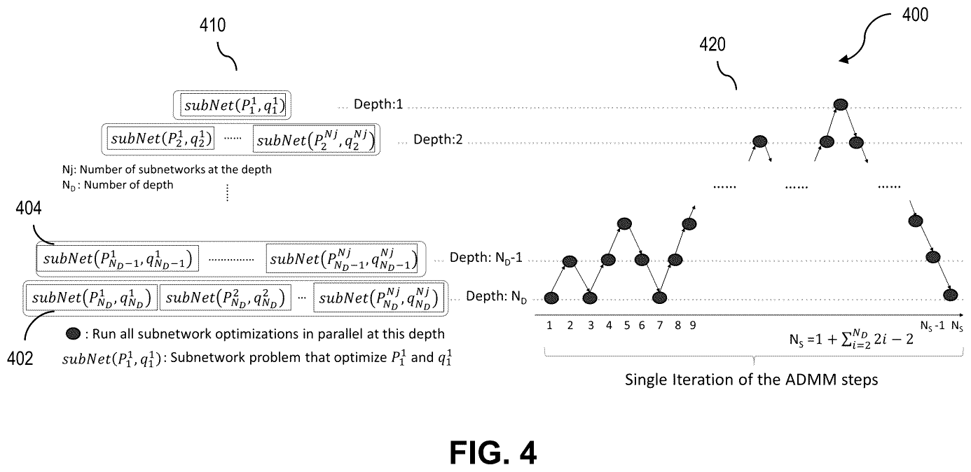

FIG. 4 illustrates a flow chart 400 demonstrating steps for network simulation, in accordance with certain embodiments. The flow chart 400 includes ADMM steps of network simulation applications at a plurality of depths, such as N_{D} depths. A large-scale network system (e.g., as shown in FIG. 1) may be decomposed into a plurality of subnetwork problems. The diagram 410 on the left-hand side describes the schematic of the plurality of subnetwork problems in the hierarchical network systems. The ADMM step scheme 420 on the right-hand side describes network simulation for one or more subnetworks in the hierarchical network systems which are associated with the corresponding depth of the network. These subnetwork problems at the same depth may be solved simultaneously or in parallel, since the corresponding one or more subnetworks do not have direct flow communication with each other. Based on the flow chart 400, the ADMM step starts from the terminal nodes (depth=N_{D}) or the well nodes. For example, the terminal nodes at depth N_{D} are associated with Nⱼ subnetworks 402 at the depth N_{D}. At the second step, the ADMM step goes up to the subnetworks 404 at the depth N_{D}−1. Once subnetworks at the shallower depth (e.g. N_{D}−1) are done, the method goes back to subnetworks at the deeper depth (e.g. N_{D}). Because the node pressure values at the shallower depth (N_{D}−1) are updated, the optimal pressure and flux can be changed at the subnetworks at deeper depth (N_{D}). The subnetwork problems of each depth are iteratively solved in this order as shown in FIG. 4. As a result, the ADMM steps may be repeated until the corresponding objective function converges.

ADMM for Network Optimization with Choke

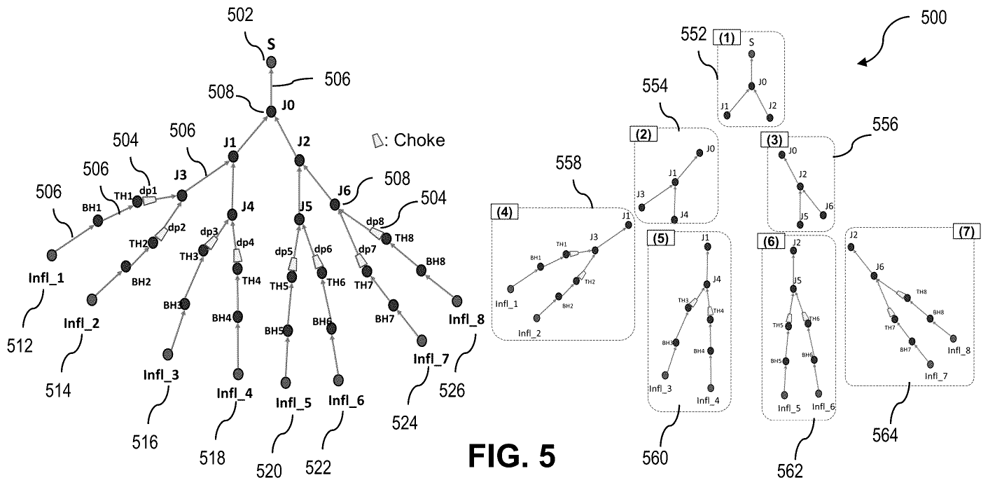

FIG. 5 illustrates a schematic representation of a simple network system 500 for ADMM optimization with choke size and its subnetworks on the right hand side, in accordance with certain embodiments. In some embodiments, the ADMM optimization methods may be applied to solve surface network problems with choke size optimization. The network system 500 may be a black oil type network flow system. The network system 500 has a separator 502 at the top and a plurality of reservoir nodes, such as eight wells 512, 514, 516, 518, 520, 522, 524, and 526. Each well has a choke 504 that can add pressure drop (DP) to selectively produce oil to maximize the oil production for the gathering system. First, the ADMM optimization method may be run with zero choke pressure drops for the eight wells to initialize the pressure and multiphase flux for all links 506 and nodes 508. Thus, the network system 500 may be decomposed into seven subnetworks 552, 554, 556, 558, 560, 562, and 564.

In some embodiments, the subnetwork optimization begins from the source subnetwork 552 by solving the optimization problem associated with subnetwork 552. The optimization problem for subnetwork 552 may be written as follows:

$$maximize {q}_{oil}^{J 1 - J 0} + {q}_{oil}^{J 2 - J 0} - {w}_{1} ( {q}_{water}^{J 1 - J 0} + {q}_{water}^{J 2 - J 0} ) + {w}_{2} ( {q}_{gas}^{J 1 - J 0} + {q}_{gas}^{J 2 - J 0} ) \qquad ( 20 )$$

$$subject to {P}_{J 1}^{k + 1} \leq {P}_{J 1}^{0} , {P}_{J 2}^{k + 1} \leq {P}_{J 2}^{0}$$

where qₒᵢₗ^{J1-J0} is the oil phase flux between node J1 and J0, q_{water}^{J0-J1} is the water phase flux between node J1 and J0, q_{gas}^{J1-J0} is the gas phase flux between node J1 and J0, P_{J1}^{k+1} is pressure at node J1 at new iteration step k+1, P_{J1}⁰ is initialized pressure value at node J1 in the first step of this workflow, and w₁ and w₂ are the weights for water and gas fluxes.

In some embodiments, as constraints, the calculated node pressures are limited to be smaller than the initial estimation of those node pressure values. Since the chokes are set for all wells in the lowest level of subnetworks, it is possible that the pressure at node J1 and J2 is smaller than the initial guess, which is calculated based on zero choke pressure drops for the eight wells 512, 514, 516, 518, 520, 522, 524, and 526. Once choke pressure drop is added at some of the eight wells, the pressure at downstream nodes may decrease. The decision variables of this optimization problem are q_{liquid}^{J1-J0} and q_{liquid}^{J2-J0}. Once this subnetwork optimization is done, the pressure at J0, J1 and J2 are updated. The key idea behind this optimization is that fluxes with high oil cut are increased and fluxes with low oil cut are decreased, while honoring the constraints. The augmented Lagrangian (objective function) of this problem is provided below.

In some embodiments, the next step to solve the second level subnetwork optimization problems associated with the subnetwork 554 after the subnetwork optimization associated with the subnetwork 552 is conducted. The optimization problem of the subnetwork 554 can be written as follows:

$$maximize {q}_{oil}^{J 3 - J 1} + {q}_{oil}^{J 4 - J 1} - {w}_{1} ( {q}_{water}^{J 3 - J 1} + {q}_{water}^{J 4 - J 1} ) + {w}_{2} ( {q}_{gas}^{J 3 - J 1} + {q}_{gas}^{J 4 - J 1} ) \qquad ( 21 )$$

$$subject to {P}_{J 3}^{k + 1} \leq {P}_{J 3}^{0} , {P}_{J 4}^{k + 1} \leq {P}_{J 4}^{0} ,$$

$$and$$

$${q}_{liquid}^{J 1 - J 0 , k} \geq {q}_{liquid}^{J 3 - J 1 , k + 1} + {q}_{liquid}^{J 4 - J 1 , k + 1}$$

where q_{liquid}^{J1-J0,k} is the liquid flux at the link between J1 and J0 at iteration step k, and q_{liquid}^{J3-J1,k+1} is the liquid flux at the link between J3 and J1 at iteration step k+1. The difference from the subnetwork (1) optimization is the liquid flux constraint. q_{liquid}^{J1-J0,k} is given from the optimization of subnetwork (1). In the 2^{nd} level subnetwork optimizations (subnetworks 554), the calculated flux value q_{liquid}^{J1-J0,k+1}=q_{liquid}^{J3-J1,k+1}+q_{liquid}^{J4-J1,k+1} is less than the previously calculated value q_{liquid}^{J1-J0,k}.

In some embodiments, the next step to solve the terminal level subnetwork optimization problems associated with the subnetwork 558 after the subnetwork optimization associated with the subnetwork 554 is conducted. The optimization of subnetwork 558 may be formulated as:

$$maximize {q}_{oil}^{TH 1 - J 3} + {q}_{oil}^{TH 2 - J 3} - {w}_{1} ( {q}_{water}^{TH 1 - J 3} + {q}_{water}^{TH 2 - J 3} ) + {w}_{2} ( {q}_{gas}^{TH 1 - J 3} + {q}_{gas}^{TH 2 - J 3} ) \qquad ( 22 )$$

$$subject to {P}_{J 3}^{k + 1} ( {P}_{TH 1}^{k + 1} , {dP}_{1}^{k + 1} ) = {P}_{J 3}^{k + 1} ( {P}_{J 1}^{k + 1} ) , {P}_{J 3}^{k + 1} ( {P}_{TH 2}^{k + 1} , {dP}_{2}^{k + 1} ) = {P}_{J 3}^{k + 1} ( {P}_{J 1}^{k + 1} ) ,$$

$$and$$

$${q}_{liquid}^{J 3 - J 1 , k} \geq {q}_{liquid}^{TH 1 - J 3 , k + 1} + {q}_{liquid}^{TH 2 - J 3 , k + 1}$$

where dP₁ is additional pressure drop by choke at TH1 node, and dP₂ is additional pressure drop by choke at TH2 node. The difference from the problem of subnetwork 554 is that there are pressure equality constraints. The pressure at node J3 given from upstream node TH1, P_{J3}^{k+1}(P_{TH1}^{pk+1}, dP₁), needs to be equal to the pressure at node J3 given from downstream node J1, P_{J3}^{k+1}(P_{J1}^{k+1}). The additional pressure drop given from the choke dP₁ is based on the calculated node pressure values as follows:

$${dP}_{1} = max ( {P}_{J 3}^{k + 1} ( {P}_{TH 1}^{k + 1} , {dP}_{1} = 0 ) - {P}_{{J}^{3}}^{k + 1} ( {P}_{J 1}^{k + 1} ) , 0. ) \qquad ( 23 )$$

where P_{J3}^{k+1}(P_{TH1}^{k+1}, dP₁=0) is the pressure at node J3 without considering the choke additional pressure drop. The choke pressure drop cannot be negative. The pressure at node J3 is given from upstream node TH1, P_{J3}^{k+1}(P_{TH1}^{k+1}, dP₁^{k+1}) is given by:

$${P}_{J 3}^{k + 1} ( {P}_{TH 1}^{k + 1} , {dP}_{1}^{k + 1} ) = {P}_{J 3}^{k + 1} ( {P}_{TH 1}^{k + 1} , {dP}_{1} = 0 ) - {dP}_{1}^{k + 1} \qquad ( 24 )$$

In some embodiments, the optimization reverts to the 2^{nd} level subnetworks after the terminal subnetwork optimization associated with the subnetwork 558 is conducted. In this reverse pass, the optimization problem of subnetwork 554 may be written as follows:

$$maximize {q}_{oil}^{J 3 - J 1} + {q}_{oil}^{J 4 - J 1} - {w}_{1} ( {q}_{water}^{J 3 - J 1} + {q}_{water}^{J 4 - J 1} ) + {w}_{2} ( {q}_{gas}^{J 3 - J 1} + {q}_{gas}^{J 4 - J 1} ) \qquad ( 25 )$$

$$subject to {P}_{J 3}^{k + 1} \leq {P}_{J 3}^{0} , {P}_{J 4}^{k + 1} \leq {P}_{J 4}^{0}$$

In some embodiments, when returning from the terminal level optimizations, the liquid flux constraints from Equation (21) are excluded. Since the fluid properties of J3−J1 and J4−J1 are updated at the shallower subnetworks, the optimal flux can be different for each link. Thus, the liquid flux constraints are not included upon reverting to the subnetwork optimization of the terminal nodes. The method iterates these subnetwork optimizations repeatedly until it converges. Details of the objective functions and ADMM steps are provided below.

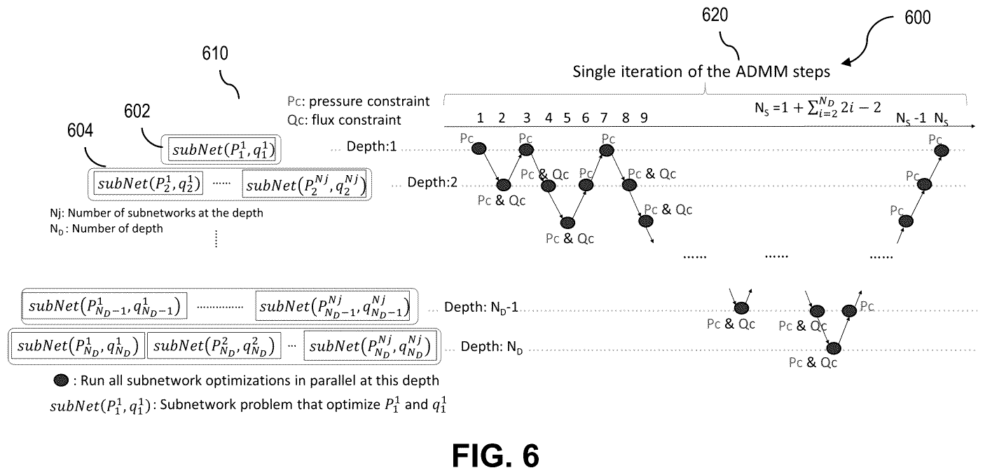

FIG. 6 illustrates a flow chart 600 demonstrating the ADMM steps for network optimization with choke, in accordance with certain embodiments. FIG. 6 explains the ADMM steps for network optimization applications with choke. The diagram 610 on the left-hand side describes the schematic of the subnetwork problems in the hierarchical network systems. The ADMM step scheme 620 on the right-hand side shows the ADMM step scheme for network optimization choke size, which is related to the depth of the network. Based on this flowchart, the ADMM step starts from a step 602 associated with the separator node (depth=1). At the second step, the ADMM step moves down to a step 604 associated with the subnetworks at the 2^{nd} depth level. Like the network simulation cases (as shown in FIG. 4), once the subnetworks at the deeper depths are completed, the process returns to the subnetworks at shallower depth levels. Once the node pressure and link flux values at the 2^{nd} depth level are updated, the optimal pressure and flux can be changed at the subnetworks at the shallower depth (depth=1). The subnetwork problems of each depth are iteratively solved in this order, as shown in FIG. 6. This ADMM steps repeats until it converges. In the flowchart of FIG. 6, the rule of the constraints in the ADMM steps are also provided. Upon moving down to deeper depths of the subnetworks, both pressure and flux constraints are included as explained in Equation 21. Upon moving up to shallower depths of the subnetworks from deeper subnetworks, only the pressure constraint is included, as explained in Equation 25.

Objective Functions for ADMM Network Optimization with Choke

In some embodiments, the ADMM optimization method may solve a convex optimization problem associated with a network system by breaking the network into a plurality of subnetworks. In particular, for the plurality of subnetworks, the ADMM optimization method may determine a plurality of objective functions and steps for ADMM network optimization with adjustable choke pressure drop. Consider again the network system shown in FIG. 5. The subnetwork optimization may be started from the source subnetwork 522. The optimization problem for subnetwork 522 may be written as follows:

$$\begin{matrix}maximize & {q}_{oil}^{J 1 - J 0} + {q}_{oil}^{J 2 - J 0} - {w}_{1} ( {q}_{water}^{J 1 - J 0} + {q}_{water}^{J 2 - J 0} ) + {w}_{2} ( {q}_{gas}^{J 1 - J 0} + {q}_{gas}^{J 2 - J 0} ) \\ subject to & {P}_{J 1}^{k + 1} \leq {P}_{J 1}^{0} , {P}_{J 2}^{k + 1} \leq {P}_{J 2}^{0}\end{matrix} \qquad ( 26 )$$

In some embodiments, the augmented Lagrangian (objective function) may be written as:

$${L}_{ρ} = - ( {q}_{oil}^{J 1 - J 0} + {q}_{oil}^{J 2 - J 0} ) - {w}_{1} ( {q}_{water}^{J 1 - J 0} + {q}_{water}^{J 2 - J 0} ) + {w}_{2} ( {q}_{gas}^{J 1 - J 0} + {q}_{gas}^{J 2 - J 0} ) + {y}_{J 1} \{ max ( 0. , {P}_{J 1}^{k + 1} - {P}_{J 1}^{0} ) \} + {y}_{J 2} \{ max ( 0. , {P}_{J 2}^{k + 1} - {P}_{J 2}^{0} ) \} + \frac{ρ}{2} {‖ max ( 0. , {P}_{J 1}^{k + 1} - {P}_{J 1}^{0} ) + max ( 0. , {P}_{J 2}^{k + 1} - {P}_{J 2}^{0} ) ‖}_{2}^{2} \qquad ( 27 )$$

In some embodiments, the decision variables are q_{liquid}^{J1-J0} and q_{liquid}^{J2-J0}, and once the multiphase fluxes are determined, the middle node pressure P_{J0}^{k+1} is computed. The dual variables can be updated as:

$${y}_{J 1}^{k + 1} = {y}_{J 1}^{k} + ρ ( max ( 0. , {P}_{J 1}^{k + 1} - {P}_{J 1}^{0} ) ) \\ {y}_{J 2}^{k + 1} = {y}_{J 2}^{k} + ρ ( max ( 0. , {P}_{J 2}^{k + 1} - {P}_{J 2}^{0} ) ) \qquad ( 28 )$$

In some embodiments, the optimization problem of subnetwork 554 may be written as:

$$\begin{matrix}maximize & \begin{matrix}{q}_{oil}^{J 3 - J 1} + {q}_{oil}^{J 4 - J 1} - {w}_{1} ( {q}_{water}^{J 3 - J 1} + {q}_{water}^{J 4 - J 1} ) + \\ {w}_{2} ( {q}_{gas}^{J 3 - J 1} + {q}_{gas}^{J 4 - J 1} )\end{matrix} \\ subject to & \begin{matrix}{P}_{J 3}^{k + 1} \leq {P}_{J 3}^{0} , {P}_{J 4}^{k + 1} \leq {P}_{J 4}^{0} , and \\ {q}_{liquid}^{J 1 - J 0 , k} \geq {q}_{liquid}^{J 3 - J 1 , k + 1} + {q}_{liquid}^{J 4 - J 1 , k + 1}\end{matrix}\end{matrix} \qquad ( 29 )$$

In some embodiments, for this subnetwork problem, the augmented Lagrangian (objective function) may be written as:

$${L}_{ρ} = - ( {q}_{oil}^{J 3 - J 1} + {q}_{oil}^{J 4 - J 1} ) - {w}_{1} ( {q}_{water}^{J 3 - J 1} + {q}_{water}^{J 4 - J 1} ) + \qquad ( 30 )$$

$${w}_{2} ( {q}_{gas}^{J 3 - J 1} + {q}_{gas}^{J 4 - J 1} ) + {y}_{J 3} \{ max ( 0. , {P}_{J 3}^{k + 1} - {P}_{J 3}^{0} ) \} +$$

$${y}_{J 4} \{ max ( 0. , {P}_{J 4}^{k + 1} - {P}_{J 4}^{0} ) \} +$$

$${y}_{J 1 \_ q} \{ max ( 0. , {q}_{liquid}^{J 3 - J 1 , k + 1} + {q}_{liquid}^{J 4 - J 1 , k + 1} - {q}_{liquid}^{J 1 - J 0 , k} ) \} +$$

$$\frac{ρ}{2} ‖ max ( 0. , {P}_{J 3}^{k + 1} - {P}_{J 3}^{0} ) + max ( 0. , {P}_{J 4}^{k + 1} - {P}_{J 4}^{0} ) +$$

$${max ( 0. , {q}_{liquid}^{J 3 - J 1 , k + 1} + {q}_{liquid}^{J 4 - J 1 , k + 1} - {q}_{liquid}^{J 1 - J 0 , k} ) ‖}_{2}^{2}$$

In some embodiments, the decision variables are q_{liquid}^{J3-J1} and q_{liquid}^{J4-J1}, and once the J4-J1 multiphase fluxes are determined, the middle node pressure P_{J1}^{k+1} is computed. The dual variables may be updated as:

$${y}_{J 3}^{k + 1} = {y}_{J 3}^{k} + ρ ( max ( 0. , {P}_{J 3}^{k + 1} - {P}_{J 3}^{0} ) ) \\ {y}_{J 4}^{k + 1} = {y}_{J 4}^{k} + ρ ( max ( 0. , {P}_{J 4}^{k + 1} - {P}_{J 4}^{0} ) ) \\ {y}_{J 1 \_ q}^{k + 1} = {y}_{J 1 \_ q}^{k} + ρ ( max ( 0. , {q}_{liquid}^{J 3 - J 1 , k + 1} + {q}_{liquid}^{J 4 - J 1 , k + 1} - {q}_{liquid}^{J 1 - J 0 , k} ) ) \qquad ( 31 )$$

In some embodiments, the terminal level subnetwork optimization is conducted. The optimization of subnetwork 558 may be formulated as:

$$\begin{matrix}maximize & \begin{matrix}{q}_{oil}^{TH 1 - J 3} + {q}_{oil}^{TH 2 - J 3} - {w}_{1} ( {q}_{water}^{TH 1 - J 3} + {q}_{water}^{TH 2 - J 3} ) + \\ {w}_{2} ( {q}_{gas}^{TH 1 - J 3} + {q}_{gas}^{TH 2 - J 3} )\end{matrix} \\ subject to & \begin{matrix}{P}_{J 3}^{k + 1} ( {P}_{TH 1}^{k + 1} , {dP}_{1} ) = {P}_{J 3}^{k + 1} ( {P}_{J 1}^{k + 1} ) , {P}_{J 3}^{k + 1} ( {P}_{TH 2}^{k + 1} , {dP}_{2} ) = \\ {P}_{J 3}^{k + 1} ( {P}_{J 1}^{k + 1} ) , and {q}_{liquid}^{J 3 - J 1 , k} \geq {q}_{liquid}^{TH 1 - J 3 , k + 1} + {q}_{liquid}^{TH 2 - J 3 , k + 1}\end{matrix}\end{matrix} \qquad ( 32 )$$

In some embodiments, the augmented Lagrangian (objective function) may be written as:

$${L}_{ρ} = - ( {q}_{oil}^{TH 1 - J 3} + {q}_{oil}^{TH 2 - J 3} ) - {w}_{1} ( {q}_{water}^{TH 1 - J 3} + {q}_{water}^{TH 2 - J 3} ) + \qquad ( 33 )$$

$${w}_{2} ( {q}_{gas}^{TH 1 - J 3} + {q}_{gas}^{TH 2 - J 3} ) + {y}_{TH 1} \{ {P}_{J 3}^{k + 1} ( {P}_{TH 1}^{k + 1} , {dP}_{1} ) -$$

$${P}_{J 3}^{k + 1} ( {P}_{J 1}^{k + 1} ) \} + {y}_{TH 2} \{ {P}_{J 3}^{k + 1} ( {P}_{TH 2}^{k + 1} , {dP}_{2} ) - {P}_{J 3}^{k + 1} ( {P}_{J 1}^{k + 1} ) \} +$$

$${y}_{J 3 \_ q} \{ max ( 0. , {q}_{liquid}^{J 3 - J 1 , k + 1} + {q}_{liquid}^{J 4 - J 1 , k + 1} - {q}_{liquid}^{J 1 - J 0 , k} ) \} +$$

$$\frac{ρ}{2} ‖ \{ {P}_{J 3}^{k + 1} ( {P}_{TH 1}^{k + 1} , {dP}_{1} ) - {P}_{J 3}^{k + 1} ( {P}_{J 1}^{k + 1} ) \} + \{ {P}_{J 3}^{k + 1} ( {P}_{TH 2}^{k + 1} , {dP}_{2} ) - {P}_{J 3}^{k + 1} ( {P}_{J 1}^{k + 1} ) \} +$$

$${max ( 0. , {q}_{liquid}^{TH 1 - J 3 , k + 1} + {q}_{liquid}^{TH 2 - J 3 , k + 1} - {q}_{liquid}^{J 3 - J 1 , k} ) ‖}_{2}^{2}$$

In some embodiments, the decision variables are q_{liquid}^{TH1-J3} and q_{liquid}^{TH2-J3}, and once the multiphase fluxes are determined, the pressure of all middle nodes in the subnetwork 554 may be computed. The dual variables can be updated as:

$${y}_{TH 1}^{k + 1} = {y}_{TH 1}^{k} + ρ ( {P}_{J 3}^{k + 1} ( {P}_{TH 1}^{k + 1} , {dP}_{1} ) - {P}_{J 3}^{k + 1} ( {P}_{J 1}^{k + 1} ) ) \\ {y}_{TH 2}^{k + 1} = {y}_{TH 2}^{k} + ρ ( {P}_{J 3}^{k + 1} ( {P}_{TH 2}^{k + 1} , {dP}_{2} ) - {P}_{J 3}^{k + 1} ( {P}_{J 1}^{k + 1} ) ) \\ {y}_{J 3 \_ q}^{k + 1} = {y}_{J 3 \_ q}^{k} + ρ ( max ( 0. , {q}_{liquid}^{J 3 - J 1 , k + 1} + {q}_{liquid}^{J 4 - J 1 , k + 1} - {q}_{liquid}^{J 1 - J 0 , k} ) ) \qquad ( 34 )$$

In some embodiments, upon reaching the terminal subnetworks, the ADMM steps revert from terminal subnetworks to source subnetworks. Therefore, the next subnetwork problems solved are at the 2^{nd} level. In this situation, the optimization problem of subnetwork 554 may be written as follows:

$$\begin{matrix}maximize & {q}_{oil}^{J 3 - J 1} + {q}_{oil}^{J 4 - J 1} - {w}_{1} ( {q}_{water}^{J 3 - J 1} + {q}_{water}^{J 4 - J 1} ) + {w}_{2} ( {q}_{gas}^{J 3 - J 1} + {q}_{gas}^{J 4 - J 1} ) \\ subject to & {P}_{J 3}^{k + 1} \leq {P}_{J 3}^{0} , {P}_{J 4}^{k + 1} \leq {P}_{J 4}^{0}\end{matrix} \qquad ( 35 )$$

In some embodiments, the augmented Lagrangian (objective function) can be written

as:

$${L}_{ρ} = - ( {q}_{oil}^{J 3 - J 1} + {q}_{oil}^{J 4 - J 1} ) - {w}_{1} ( {q}_{water}^{J 3 - J 1} + {q}_{water}^{J 4 - J 1} ) + {w}_{2} ( {q}_{gas}^{J 3 - J 1} + {q}_{gas}^{J 4 - J 1} ) + {y}_{J 3} \{ max ( 0. , {P}_{J 3}^{k + 1} - {P}_{J 3}^{0} ) \} + {y}_{J 4} \{ max ( 0. , {P}_{J 4}^{k + 1} - {P}_{J 4}^{0} ) \} + \frac{ρ}{2} {‖ max ( 0. , {P}_{J 3}^{k + 1} - {P}_{J 3}^{0} ) + max ( 0. , {P}_{J 4}^{k + 1} - {P}_{J 4}^{0} ) ‖}_{2}^{2} \qquad ( 36 )$$

In some embodiments, as explained in the previous section, upon moving back from the terminal level optimizations, the liquid flux constraints from Equation (29) are excluded.

### Proxy Models for Multiphase Flow Consideration

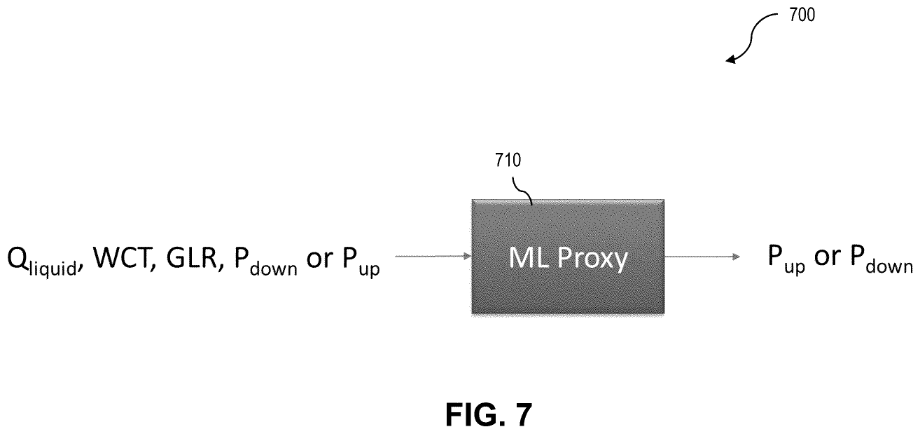

FIG. 7 illustrates a schematic representation 700 of a machine learning based proxy model for multiphase flow correlation, in accordance with certain embodiments. The ADMM optimization methods may further enhance the efficiency of the proposed ADMM network optimization by using a plurality of proxy models for multiphase flow correlation. In some embodiments, the calculation of pipe flow correlation takes about 90% of the calculation time in the whole formulation. Therefore, a machine learning (ML) algorithm may be used to determine one or more proxy models to significantly improve the computational efficiency by replacing the multiphase pipe flow correlation with the one or more proxy models. The one or more proxy models may be determined using nput data, such as liquid flux, water cut, gas liquid ratio, and one side node pressure. The output of the one or more proxy models may be the other side node pressure. For example, the ADMM optimization methods may train a ML-based proxy model 710 to predict one side node pressure, such as Pᵤₚ in a multi-phase flow based on a plurality of parameters, such as Q_{liquid}, WCT, GLR, and one side node pressure P_{down}. Likewise, the ADMM optimization methods may train a ML-based proxy model 710 to predict one side node pressure, such as P_{down} in a multi-phase flow based on a plurality of parameters, such as Q_{liquid}, WCT, GLR, and one side node pressure Pᵤₚ. Although other fluid properties may affect the pressure calculation, such as density, compressibility, and solution gas-oil ratio, these have only minor effects on pressure calculation.

In some embodiments, as the first step of building the proxy models, the ADMM optimization methods may initialize the pressure and multiphase fluxes for the network system of interest. The pressure and flux initialization approach is explained below. Then, these initialized values are used to take the ranges of the proxy parameters to generate the training dataset. The ranges of the parameters are determined as follows:

$$0.01 < {Q}_{liq \_ ini} < 2 {Q}_{liq \_ ini} , 0.5 ini < {P}_{ini} < 1.5 {P}_{ini} \\ min ( WCT ) of connected reservoirs < WCT < max ( WCT ) of connected reservoirs \\ min ( GLR ) of connected reservoirs < GLR < max ( GLR ) of connected reservoirs \qquad ( 37 )$$

In some embodiments, the the ML-based proxy model may be selected from a pluriaty of machine learning models generated using a linear regression algorithm, a cubic/polynomial regression algorithm, a random forest algorithm, a support vector machine algorithm, and/or a neural network. A synthetic dataset is used to test the plurality of machine learning models. The synthetic dataset includes 10,000 samples for each link of the network generated by using the Latin Hypercube Sampling (LHS). Thus, the ML-based proxy model 710 is selected from a best model from the plurality of machine learning models for the ADMM applications. Cross validation may be used to tune the ML parameters for the pluriaty of machine learning models. For example, a random forest model includes a plurilaty of tuning parameters, such as number of trees, maximum tree depth, etc. As another example, a support vector machine model includes a plurilaty of tuning parameters, such as kernel type, regularization parameters, tolerance, etc. As another example, a neural network includes a plurlaity of tuning parameters, such as number of layers, number of nodes, regularization parameters, tolerance, learing rate, etc.

In some embodiments, the training procedure may be done offline with one time computational cost and can be used subsequently for all further network simulation and optimization steps. If any of the operating conditions used in developing the ML models exceed the initial ranges, then the ML model may have to be retrained. If measurement data is available to calibrate any of the links, then a combination of physics and ML model may be used as a hybrid ML model.

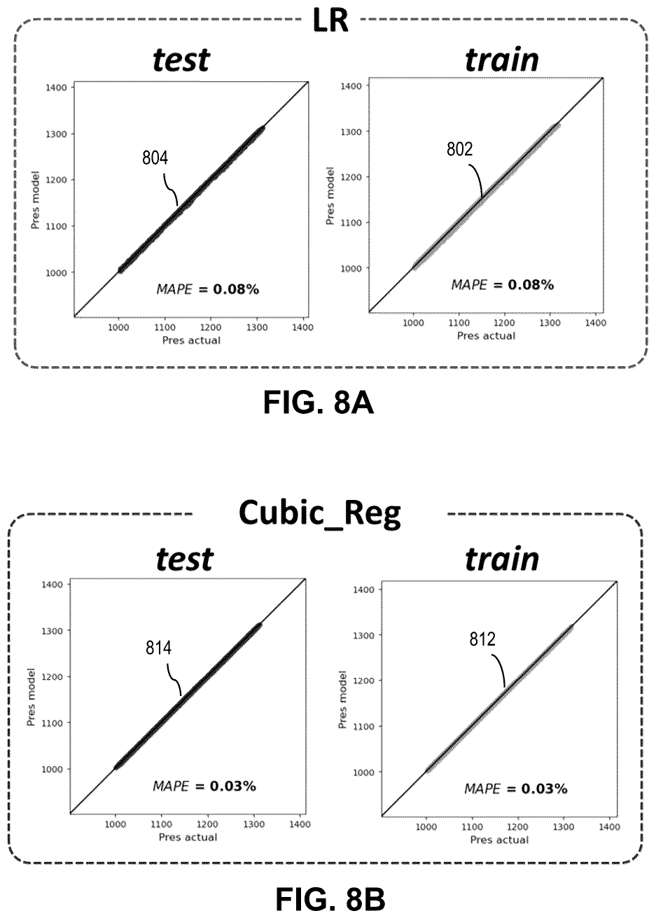

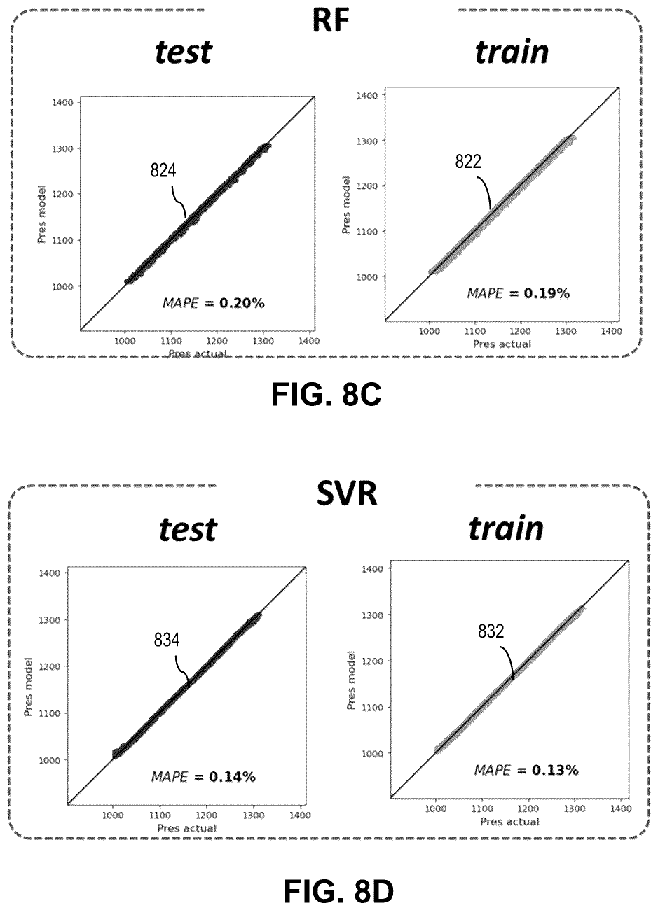

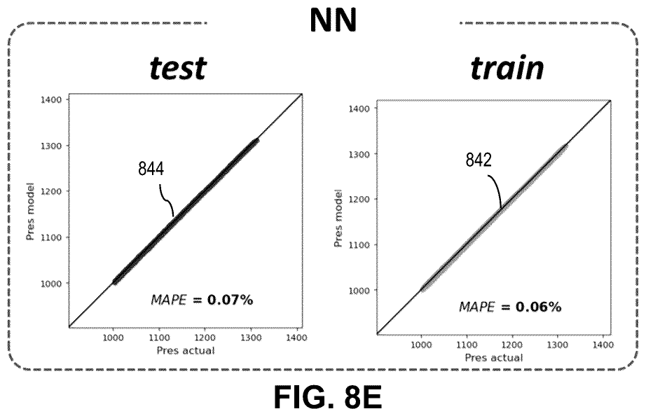

FIGS. 8A-8E illustrate a set of plots showing training and blind test for the calculation of multiphase flow correlation, in accordance with certain embodiments. In some embodiments, the plurailty of ML models are tested using the synthetic data for a network with four wells and eleven links. Table 1 and FIGS. 8A-8E show the training and blind test performance of the five ML models. FIG. 8A shows the training 802 and blind test 804 performance for the linear regression model. FIG. 8B shows the training 812 and blind test 814 performance for the cubic regression model. FIG. 8C shows the training 822 and blind test 824 performance for the random forest model. FIG. 8D shows the training 832 and blind test 834 performance for the support vector machine model. FIG. 8E shows the training 842 and blind test 844 performance for the neural network. In these five ML models, the cubic regression model provides the best training (0.0328%) and blind test (0.0329%) performance based on mean absolute percent error (MAPE). Thus, the disclosed ADMM optmization methods may use cubic regression as an ML model for the pipe flow correlation proxy in the ADMM formulations.

In some embodiments, in the network optimization problems, the proxy models for the multiphase flow correlation need to be very accurate. The error of the proxy model can be accumulated during the ADMM iterations, leading to inaccurate network optimization results. Thus, the mean absolute error of the calculated pressure by the proxy model is limited to less than 1.0 psi. Likewise, in the large-scale network system tested herein, the proxy models are very accurate and provide errors of less than 1.0 psi for the majority of the links. Therefore, such proxy models can further contribute significantly to the computational time reduction. An example of comparison of the five machine learning models for proxy models of multiphase flow correlation may be found in Table 1.

TABLE 1

| MAPE [%] | LR_train | LR_test | RF_train | RF_test | SVR_train | SVR_test | NN_train | NN_test | Cubic_train | Cubic_test |
|---|---|---|---|---|---|---|---|---|---|---|
| Link 0 | 0.0801 | 0.0789 | 0.1926 | 0.2048 | 0.1340 | 0.1370 | 0.0650 | 0.0659 | 0.0258 | 0.0266 |
| Link 1 | 0.0360 | 0.0357 | 0.1394 | 0.1454 | 0.1375 | 0.1350 | 0.0623 | 0.0625 | 0.0084 | 0.0087 |
| Link 2 | 0.0332 | 0.0340 | 0.1052 | 0.1138 | 0.1392 | 0.1397 | 0.0225 | 0.0233 | 0.0062 | 0.0060 |
| Link 3 | 0.0137 | 0.0138 | 0.0670 | 0.0745 | 0.1442 | 0.1440 | 0.1106 | 0.1120 | 0.0012 | 0.0012 |
| Link 4 | 0.0068 | 0.0069 | 0.0518 | 0.0559 | 0.1361 | 0.1409 | 0.0386 | 0.0391 | 0.0001 | 0.0001 |
| Link 5 | 0.0154 | 0.0154 | 0.0732 | 0.0816 | 0.1372 | 0.1419 | 0.0543 | 0.0579 | 0.0009 | 0.0009 |
| Link 6 | 0.0080 | 0.0081 | 0.0503 | 0.0567 | 0.1376 | 0.1414 | 0.0232 | 0.0245 | 0.0001 | 0.0001 |
| Link 7 | 0.2977 | 0.2989 | 0.2140 | 0.2295 | 0.1159 | 0.1133 | 0.0253 | 0.0255 | 0.0669 | 0.0679 |
| Link 9 | 0.0770 | 0.0793 | 0.1463 | 0.1555 | 0.1121 | 0.1135 | 0.0297 | 0.0303 | 0.0014 | 0.0013 |
| Link 11 | 0.4754 | 0.4436 | 0.2970 | 0.3175 | 0.2093 | 0.2143 | 0.1146 | 0.1255 | 0.2453 | 0.2444 |
| Link 13 | 0.0711 | 0.0736 | 0.1290 | 0.1370 | 0.1021 | 0.1005 | 0.1186 | 0.1157 | 0.0047 | 0.0048 |
| All Links | 0.1013 | 0.0989 | 0.1333 | 0.1429 | 0.1368 | 0.1383 | 0.0604 | 0.0620 | 0.0328 | 0.0329 |

### Pressure and Flux Initialization for Network Simulations

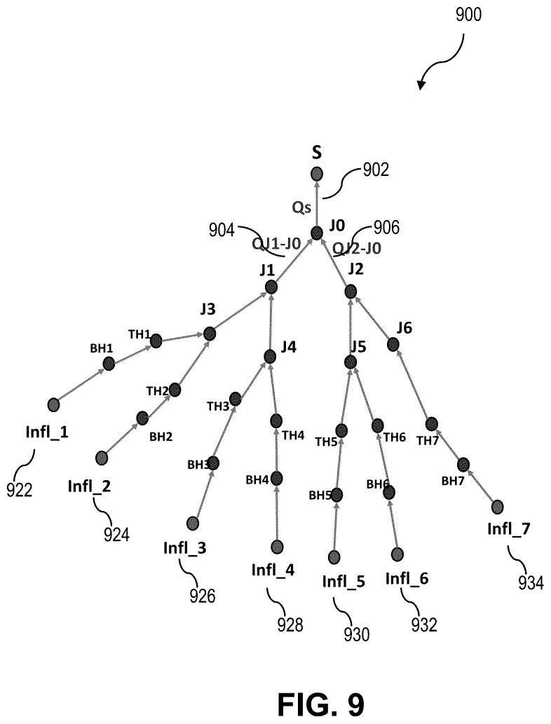

FIG. 9 illustrates a schematic representation 900 of modeling approaches for reservoir connectivity identification and production forecasting, in accordance with certain embodiments In some embodiments, the ADMM optimization methods may need a reliable initial guess of the node pressure and link flux to accurately solve the large-scale convex optimization problems. In the schematic representation 900, the ADMM optimization methods are used to solve an optimization problem with one variable, such as liquid flux Qs at source link 902. The fluxes at lower levels of links 904 and 906 are determined by using the following two different calculation options:

### Option 1:

In some embodiments, the ADMM optimization methods are used to determine the ratio of the fluxes for each branch based on the number of connected wells to the link. In the system of FIG. 9, the link 904 (e.g., J1−J0) is connected to four wells, such as well 922, well 924, well 926, and well 928, and the link 906 (e.g., J2−J0) is connected to another three wells, such as well 930, well 932, and well 934. Then, the fluxes of these two links 904 and 906 may be initialized as:

$${Q}_{J 1 - J 0} = \frac{4}{7} Qs , {Q}_{J 2 - J 0} = \frac{3}{7} Qs \qquad ( 38 )$$

where, Q_{J1-J0} is the calculated liquid flux at link 904 (e.g., J1−J0), and Q_{J2-J0} is the calculated liquid flux at link 906 (e.g., J2−J0).

### Option 2:

In some embodiments, the ADMM optimization methods are used to determine the ratio of the fluxes for each branch based on the pipe deliverability. First, the flux per unit pressure drop is calculated for every link. Then, the link flux is determined based on the calculated pipe deliverability as follows:

$${Q}_{J 1 - J 0} = \frac{{q}_{J 1 - J 0}^{unit \_ dp}}{{q}_{J 1 - J 0}^{unit \_ dp} + {q}_{J 2 - J 0}^{unit \_ dp}} Qs , {Q}_{J 2 - J 0} = \frac{{q}_{J 2 - J 0}^{unit \_ dp}}{{q}_{J 1 - J 0}^{unit \_ dp} + {q}_{J 2 - J 0}^{unit \_ dp}} Qs \qquad ( 39 )$$

where, q_{J1-J0}^{unit_dp} is liquid flux that can be flow by unit pressure drop at the link J1−J0, and q_{J2-J0}^{unit_dp} is liquid flux that can be flow by unit pressure drop at the link J2−J0.

In some embodiments, by using the above calculation recursively until the terminal nodes, the ADMM optimization methods may determine the fluxes of all links and pressure of all nodes. The decision variable Qs is optimized as follows:

$$obj = {\sum }_{i = 1}^{7} {Pwf}_{from {IPR}_{i}} - {Pwf}_{from {VLP}_{i}} , Qs = arg min ( obj ( Qs ) ) \\ {Pwf}_{from IPR \_ i} = IPR ( {P}_{res} , {Q}_{res - BH} ) , \\ {Pwf}_{from VLP \_ i} = VLP ( {P}_{TH} , {Q}_{BH - TH} ) \qquad ( 40 )$$

where, Pwƒ_{ƒrom IPR_i} is BHP at i th well calculated from reservoir node based on IPR and Pwƒ_{ƒrom VLP_i} is BHP at i th well calculated from tubing head node based on VLP.

To facilitate a better understanding of the present disclosure, the following examples of certain aspects of preferred embodiments are given. The following examples are not the only examples that could be given according to the present disclosure and are not intended to limit the scope of the disclosure or claims. To demonstrate the benefits of the disclosed ADMM optimization methods discussed above, the workflows were applied to several field cases in the following examples. In particular, the disclosed ADMM optimization methods are applied to a plurality of synthetic cases to validate the accuracy and computational efficiency of the ADMM optimization and to confirm the capability to optimize choke pressure to maximize oil production. Finally, the ADMM optimization methods are applied to a field case in order to solve for pressure and multiphase flux for all network nodes and links.

### Application of ADMM Network Simulation

In some embodiments, the disclosed ADMM optimization methods are used to apply distributed agent optimization for several gathering network simulation problems. In these applications, the separator node pressure and all reservoir node pressures are given, and the disclosed ADMM optimization methods are used to solve for all node pressure and multiphase flux for all links in a gathering system in which a black oil type flow system and uniform temperature condition are applied. In some embodiments, the gathering system includes a Vogel inflow model for IPR model, a Hagedorn and Brown model for well VLP, and a Beggs and Brill model for surface pipe flow pressure calculation. In the following cases, reservoir and fluid properties for each well are determined randomly. Thus, every well has different reservoir and fluid properties. The simulation results are compared with a reference simulator based on sequential programming.

### Small Network (Six Wells)

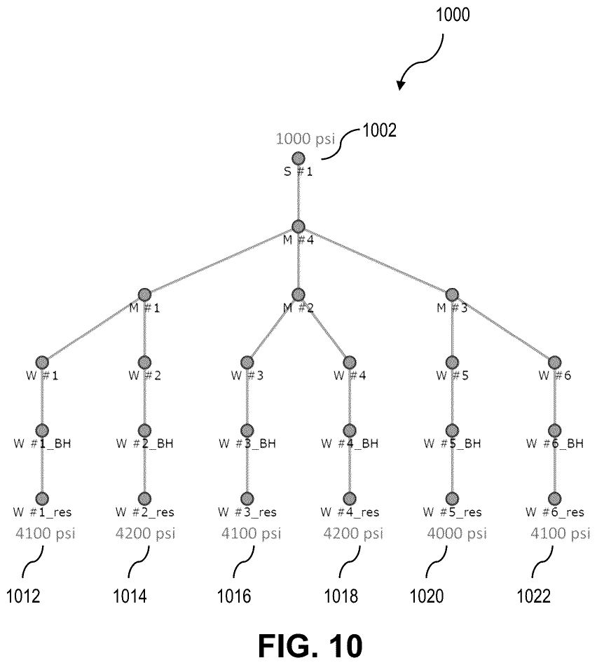

FIG. 10 illustrates a schematic representation of a network system 1000 for the application of ADMM simulation, in accordance with certain embodiments. The network system 100 include a separator node 1002 and six reservoir nodes, such as well 1012, well 1014, well 1016, well 1018, well 1020, and 1022. The pressure at the separator node and the six reservoir nodes are given as boundary conditions. In this case, the network system 1000 is an oil and gas two phase flow system.

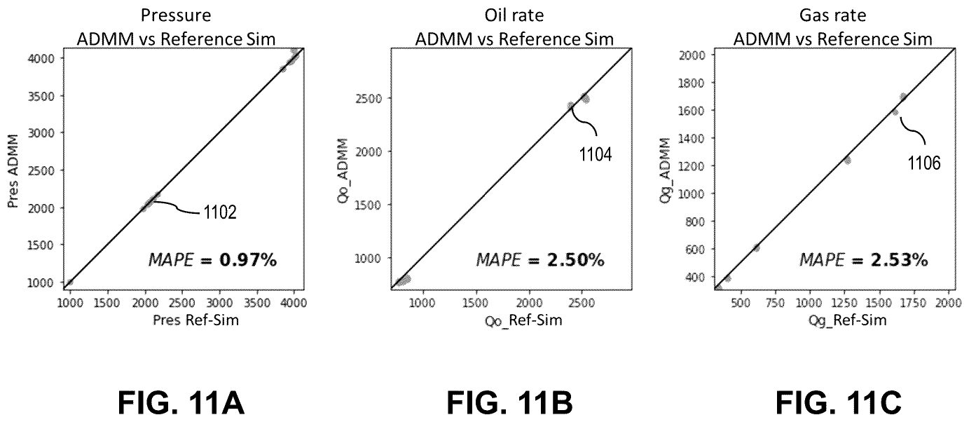

FIGS. 11A-11C illustrate plots comparing pressure and multiphase flux between ADMM and reference simulator for a six-well case, in accordance with certain embodiments. In particular, FIG. 11A shows the comparison of the calculated pressure 1102 for all nodes and links between ADMM and reference simulator with a 0.97% MAPE. FIG. 11B shows the comparison of the calculated oil rate 1104 for all nodes and links between ADMM and reference simulator with a 2.50% MAPE. FIG. 11C shows the comparison of the calculated gas rate 1106 for all nodes and links between ADMM and reference simulator with a 2.53% MAPE. Thus, the MAPE value of the calculated pressure between ADMM and reference simulator is less than 1%, and the MAPE values of multiphase fluxes are also reasonably small. Therefore, the disclosed ADMM optimization methods provide reasonable accuracy for pressure and multiphase flux calculation for the small network case.

### Middle Size Network (256 Wells)

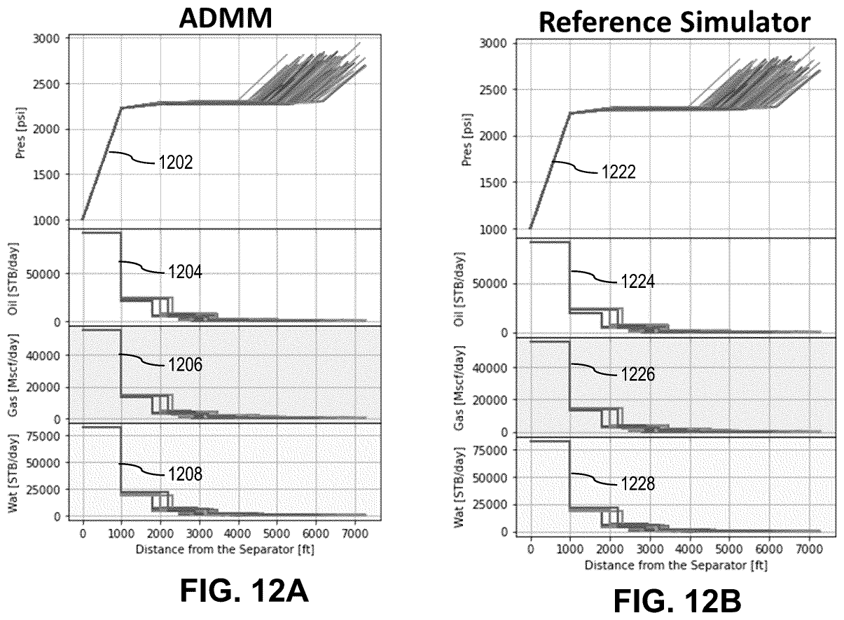

FIGS. 12A and 12B illustrate plots of calculated pressure and multiphase flux from ADMM and reference simulator for a 256-well case, in accordance with certain embodiments. In some embodiments, the network system has one separator node and 256 reservoir nodes (256 wells). The pressure at the separator node and 256 reservoir nodes are given as boundary conditions. The system has three phase flow. FIG. 12A shows the calculated node pressure 1202 and multiphase fluxes, such as oil rate 1204, gas rate 1206, and watercut 1208, from ADMM. FIG. 12B shows the calculated node pressure 1222 and multiphase fluxes, such as oil rate 1224, gas rate 1226, and watercut 1228, from the reference simulator. The horizontal axis is the distance from the separator to each junction and reservoir node. As can be seen in FIGS. 12A and 12B, the smallest pressure is at the separator point, and it increases as it goes to each junction and reservoir node. The flux becomes maximum at the source link connected to the separator, and the flux decreases as the distance goes to upstream levels of the gathering system.

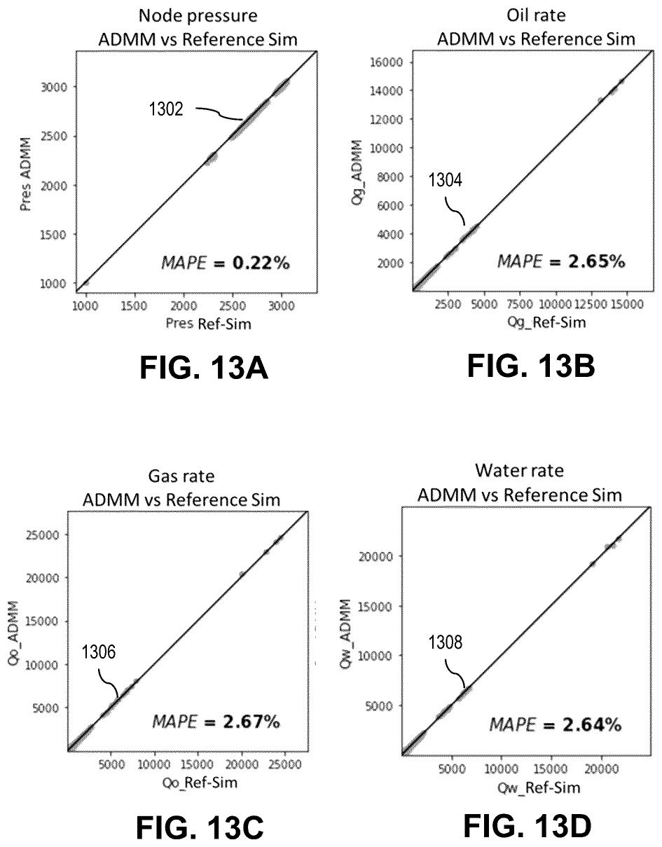

FIGS. 13A-13D illustrate plots comparing pressure and multiphase flux between ADMM and reference simulator for the 256-well case, in accordance with certain embodiments. FIG. 13A shows the comparison of the calculated pressure 1302 for all nodes and links between ADMM and reference simulator with a 0.2% MAPE. FIG. 13B shows the comparison of the calculated oil rate 1304 for all nodes and links between ADMM and reference simulator with a 2.65% MAPE. FIG. 13C shows the comparison of the calculated gas rate 1306 for all nodes and links between ADMM and reference simulator with a 2.67% MAPE. FIG. 13D shows the comparison of the calculated gas rate 1308 for all nodes and links between ADMM and reference simulator with a 2.64% MAPE. Thus, the MAPE of the calculated pressure between ADMM and reference simulator is less than 1%, and the MAPE of multiphase fluxes are also reasonably small (about 2.6%).

Application of ADMM Network Optimization with Choke

In some embodiments, the disclosed ADMM optimization methods are used to solve the optimization problems of gathering network systems to maximize oil production by changing choke pressure drops. In the following application, there is a choke for every wellhead. Same as in the above applications, one separator node pressure and all reservoir node pressures are given, and the method solves for all node pressure, multiphase flux of all links, and optimal choke pressure drops of all wells. Same as the previous applications, all wells have different fluid and reservoir properties. The black oil flow model and uniform temperature condition are applied in the following applications. In some embodiments, the gathering system includes a Vogel inflow model for IPR model, a Hagedorn and Brown model for well VLP, and a Beggs and Brill model for surface pipe flow pressure calculation.

### Small Network (Nine Wells)

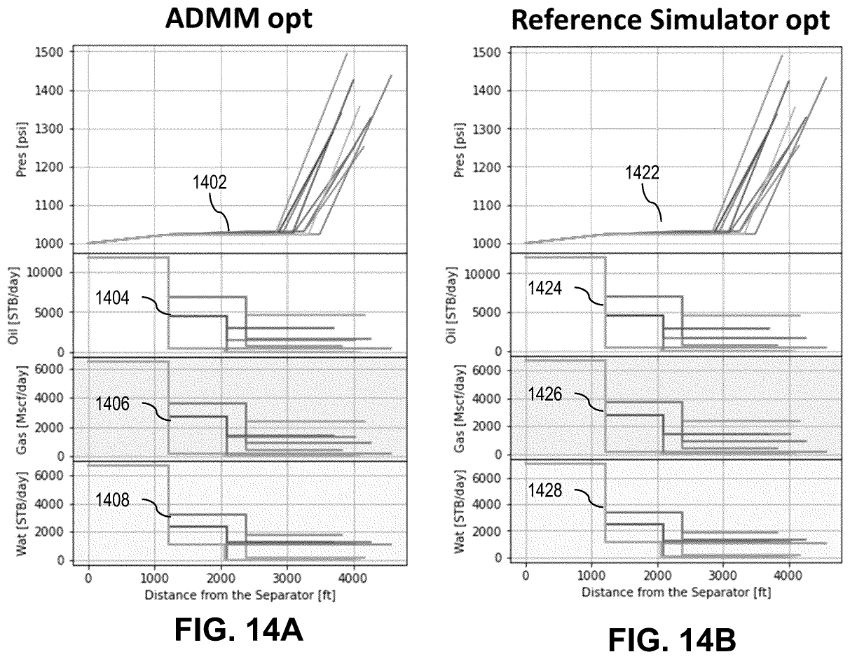

FIGS. 14A and 14B illustrate plots of calculated pressure and multiphase flux from ADMM and reference simulator optimization for a nine-well case, in accordance with certain embodiments. In this application, the network system includes one separator node and nine reservoir nodes, such as nine wells. The pressure at the separator node and nine reservoir nodes are given as boundary conditions. The system has three phase flow. An example of the optimized choke additional pressure drop of all nine producers for ADMM and reference simulator may be found in Table 2. Both ADMM and reference simulator provided choke additional pressure drop for “W6”, “W7”, and “W9”, and the values of the additional pressure drop are reasonably close to each other. FIG. 14A shows the calculated node pressure 1402 and multiphase fluxes, such as oil rate 1404, gas rate 1406, and watercut 1408, from ADMM. FIG. 14A shows the calculated node pressure 1422 and multiphase fluxes, such as oil rate 1424, gas rate 1426, and watercut 1428, from reference simulator. The horizontal axis is the distance from the separator to each junction and reservoir node. As can be seen in FIGS. 14A and 14B, the smallest pressure is at the separator point, and it increases as it goes to each junction and reservoir node. The flux becomes maximum at the source link connected to the separator, and the flux decreases as the distance goes to upstream levels of the gathering system.

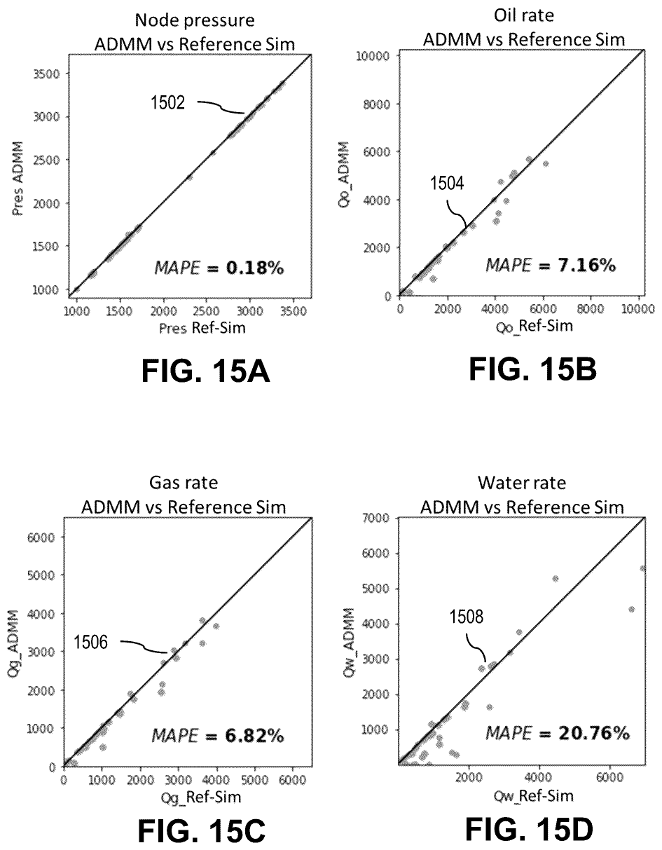

FIGS. 15A-15D illustrate plots comparing pressure and multiphase flux between ADMM and reference simulator optimization for the nine-well case, in accordance with certain embodiments. FIG. 15A shows the comparison of the calculated pressure 1502 for all nodes and links between ADMM and reference simulator with a 0.18% MAPE. FIG. 15B shows the comparison of the calculated oil rate 1504 for all nodes and links between ADMM and reference simulator with a 7.16% MAPE. FIG. 15C shows the comparison of the calculated gas rate 1506 for all nodes and links between ADMM and reference simulator with a 6.82% MAPE. FIG. 15D shows the comparison of the calculated gas rate 1508 for all nodes and links between ADMM and reference simulator with a 20.76% MAPE. Therefore, there is good agreement between ADMM and reference simulator for node pressure. On the other hand, there is a slight difference in multiphase fluxes between ADMM and reference simulator. The reason for this is that ADMM and reference simulator provided slightly different choke pressure drop values (shown in Table 2). Since this optimization problem is highly nonlinear, different methods can provide different optimization results. As long as ADMM provides the same level of oil production increment with reference simulator, it is not an issue that these two optimization methods provide different choke pressure drop values. Table 3 shows the increased amount of oil production after choke pressure drop optimization. Although the reference simulator shows a slightly larger oil production increment, those two methods provided the same level of oil production increment by optimizing the wellhead choke pressure drop.

TABLE 2

| Well | ADMM [psi] | Reference Simulator [psi] |
|---|---|---|
| W1 | 0.00027 | 0 |
| W2 | 0 | 0 |
| W3 | 0 | 0 |
| W4 | 0 | 0 |
| W5 | 0 | 0 |
| W6 | 1662.44 | 1664.08 |
| W7 | 1271.52 | 1213.55 |
| W8 | 0 | 0 |
| W9 | 1861.1 | 1862.31 |

TABLE 3

| Optimizer | Oil rate [bbl/day] |
|---|---|
| Reference simulator | +115.5 |
| ADMM | +109.0 |

### Medium Size Network (256 Wells)

In some embodiments, the network system includes one separator node and 256 reservoir nodes, such as 256 wells. The pressure at the separator node and 256 reservoir nodes are given as boundary conditions. The system has three phase flow.

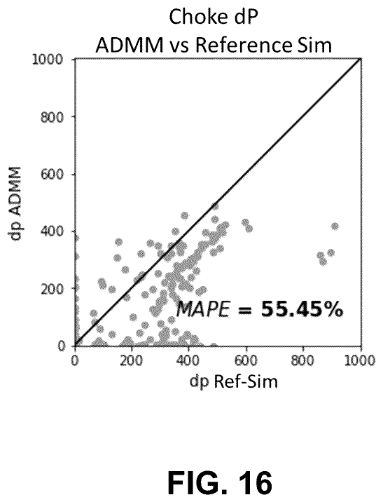

FIG. 16 illustrates a plot comparing optimized choke pressure drop between ADMM and reference simulator optimization for a 256-well case, in accordance with certain embodiments. The calculated MAPE is 55.45%, which indicates that ADMM and reference simulator find different solutions for the optimal choke pressure drops. If ADMM provides a similar level of oil production increment as the reference simulator, it is not an issue that these two optimization methods provide different choke pressure drop values.

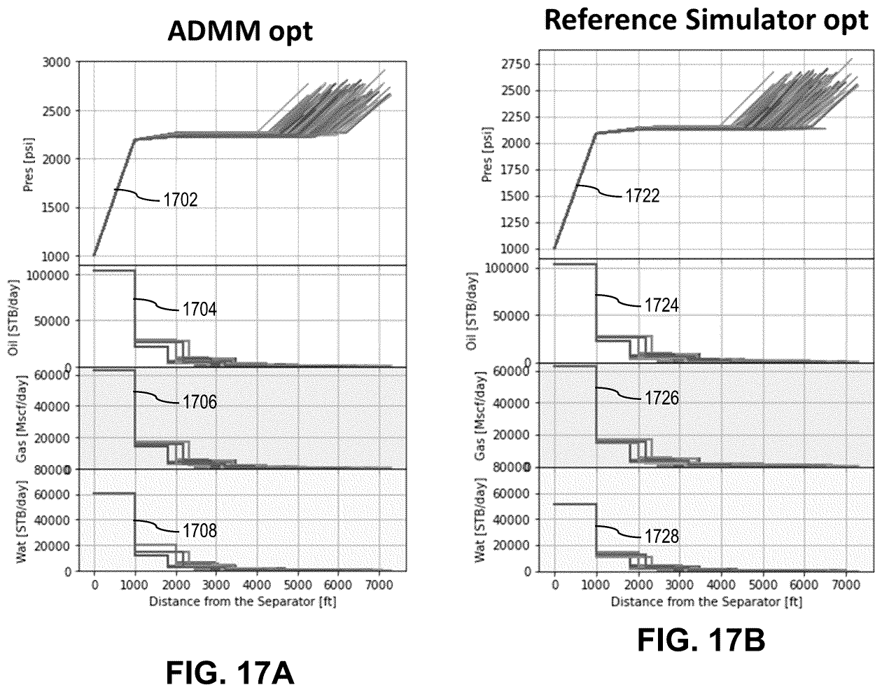

FIGS. 17A and 17B illustrate plots of calculated pressure and multiphase flux from ADMM and reference simulator optimization for the 256-well case, in accordance with certain embodiments. FIG. 17A shows the calculated node pressure 1702 and multiphase fluxes, such as oil rate 1704, gas rate 1706, and watercut 1708, from ADMM. FIG. 17A shows the calculated node pressure 1722 and multiphase fluxes, such as oil rate 1724, gas rate 1726, and watercut 1728, from reference simulator. The horizontal axis is the distance from the separator to each junction and reservoir node. As can be seen in FIGS. 17A and 17B, the smallest pressure is at the separator point, and it increases as it goes to each junction and reservoir node. The flux becomes maximum at the source link connected to the separator, and the flux decreases as the distance goes to upstream levels of the gathering system.

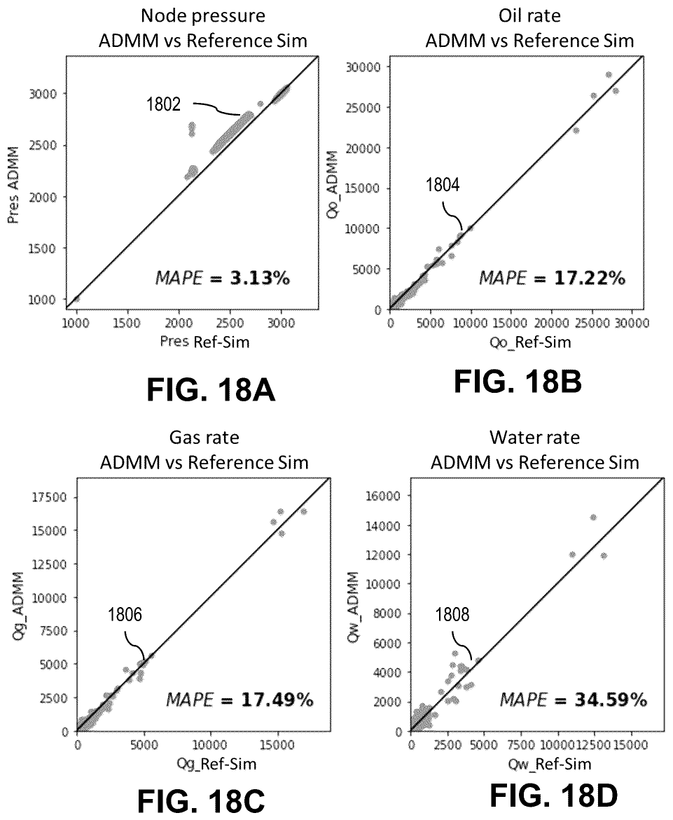

FIGS. 18A-18D illustrate plots comparing pressure and multiphase flux between ADMM and reference simulator optimization for the 256-well case, in accordance with certain embodiments. FIG. 18A shows the comparison of the calculated pressure 1802 for all nodes and links between ADMM and reference simulator with a 3.13% MAPE. FIG. 18B shows the comparison of the calculated oil rate 1804 for all nodes and links between ADMM and reference simulator with a 17.22% MAPE. FIG. 18C shows the comparison of the calculated gas rate 1806 for all nodes and links between ADMM and reference simulator with a 17.49% MAPE. FIG. 18D shows the comparison of the calculated gas rate 1808 for all nodes and links between ADMM and reference simulator with a 34.59% MAPE. ADMM obtained a slightly higher node pressure than the reference simulator while satisfying all physical constraints at nodes for pressure and volume balances. Since this optimization problem is highly nonlinear, different methods may provide different optimization results. Table 4shows the increased amount of oil production after choke pressure drop optimization. In this case, ADMM optimization provided a slightly larger oil production increment from the choke pressure drop optimization, although both methods show similar performance.

TABLE 4

| Optimizer | Oil rate [bbl/day] |
|---|---|
| Reference simulator | +11744.1 |
| ADMM | +12356.7 |

### Large Network (1024 Wells)

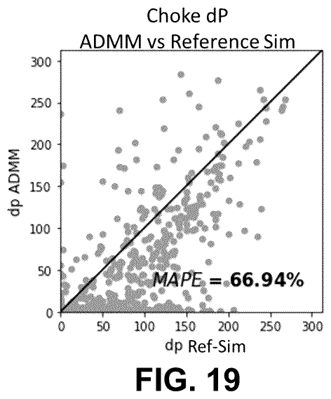

FIG. 19 illustrates a plot comparing optimized choke pressure drop between ADMM and reference simulator optimization for a 1024-well case, in accordance with certain embodiments. In this application, there is one separator node and 1024 reservoir nodes (1024 wells). The pressure at the separator node and 1024 reservoir nodes are given as boundary conditions. The gathering system has three phase flow. The calculated MAPE is 66.94%, which indicates that ADMM and reference simulator find different solutions for the optimal choke pressure drops same as the middle-size network case.

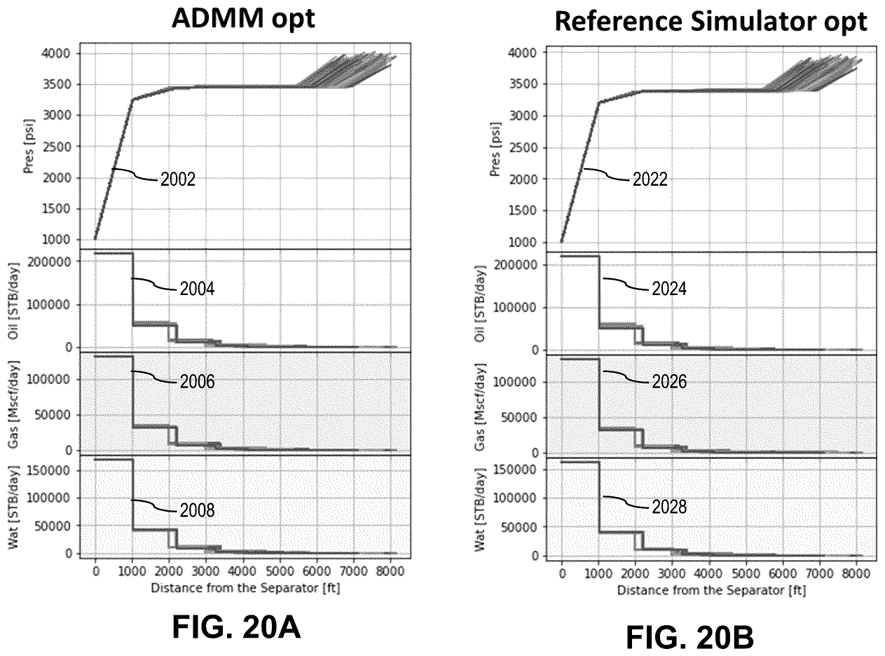

FIGS. 20A and 20B illustrate plots of calculated pressure and multiphase flux from ADMM and reference simulator optimization for the 1024-well case, in accordance with certain embodiments. FIG. 20A shows the calculated node pressure 2002 and multiphase fluxes, such as oil rate 2004, gas rate 2006, and watercut 2008, from ADMM. FIG. 20A shows the calculated node pressure 2022 and multiphase fluxes, such as oil rate 2024, gas rate 2026, and watercut 2028, from reference simulator. The horizontal axis is the distance from the separator to each junction and reservoir node. As can be seen in FIGS. 20A and 20B, the smallest pressure is at the separator point, and it increases as it goes to each junction and reservoir node. The flux becomes maximum at the source link connected to the separator, and the flux decreases as the distance goes to upstream levels of the gathering system.

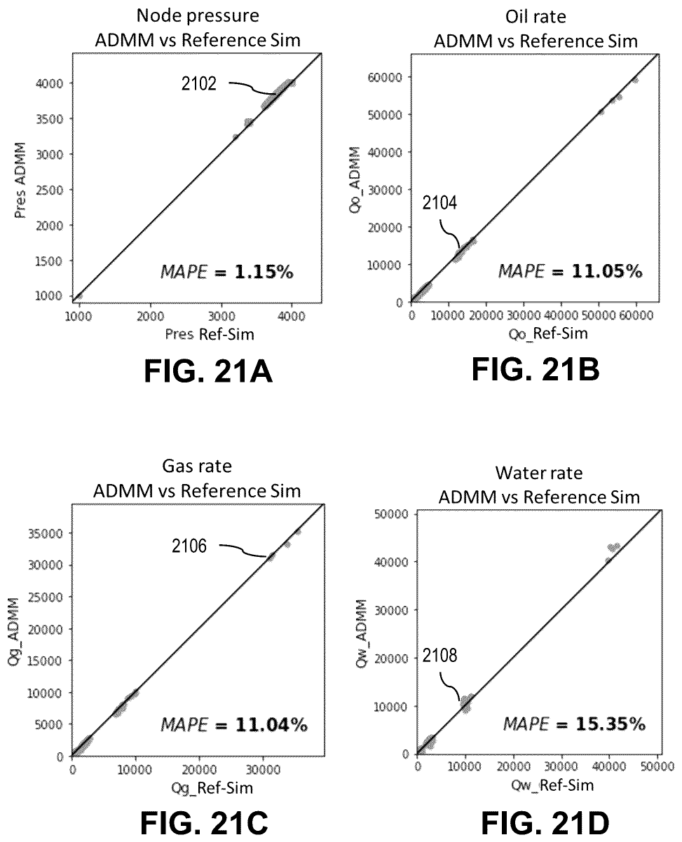

FIGS. 21A-21D illustrate plots comparing pressure and multiphase flux between ADMM and reference simulator optimization for the 1024-well case, in accordance with certain embodiments. FIG. 21A shows the comparison of the calculated pressure 2102 for all nodes and links between ADMM and reference simulator with a 1.15% MAPE. FIG. 21B shows the comparison of the calculated oil rate 2104 for all nodes and links between ADMM and reference simulator with a 11.05% MAPE. FIG. 21C shows the comparison of the calculated gas rate 2106 for all nodes and links between ADMM and reference simulator with a 11.04% MAPE. FIG. 21D shows the comparison of the calculated gas rate 2108 for all nodes and links between ADMM and reference simulator with a 15.35% MAPE. There is good agreement for node pressure, and slight differences in multiphase fluxes are detected between ADMM and reference simulator. Table 5 shows the increased amount of oil production after choke pressure drop optimization. In this case, reference simulator optimization provided a slightly larger oil production increment from the choke pressure drop optimization, although both methods show similar performance. This result indicates that the disclosed ADMM optimization framework works properly for choke size optimization and provides similar oil production increment performance with reference simulator.

TABLE 5

| Optimizer | Oil rate [bbl/day] |
|---|---|
| Reference simulator | +28208.3 |
| ADMM | +26739.8 |

### Comparison of Computational Time

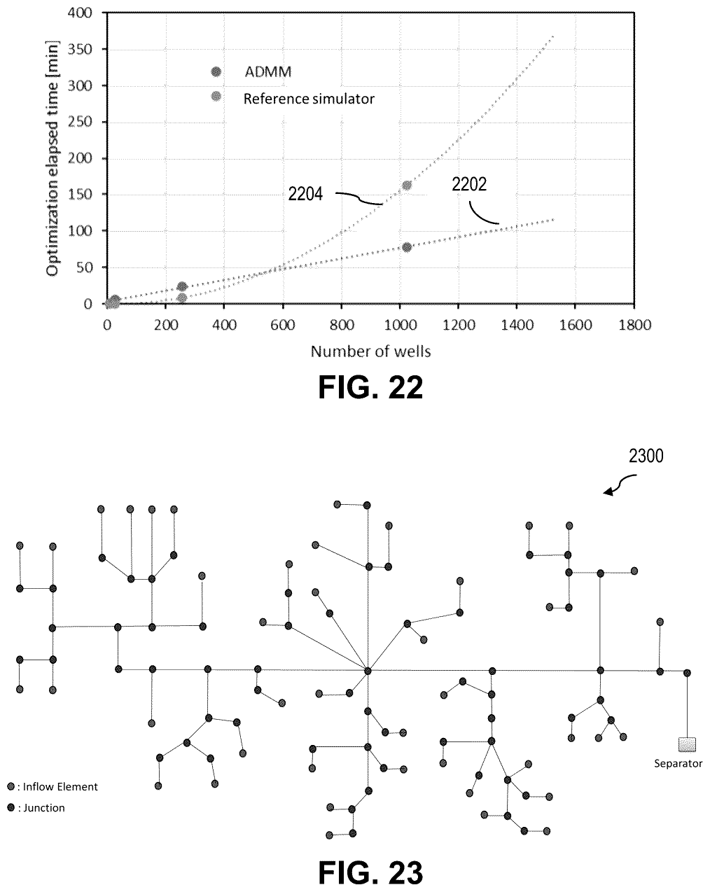

FIG. 22 illustrates a plot comparing the computational time between the reference simulator and ADMM for different sizes of networks, in accordance with certain embodiments. In some embodiments, a computational time 2202 of ADMM for the choke pressure drop optimization is compared to a computational time 2204 of reference simulator for four different gathering network size problems. Table 6 shows the computational time of the network optimization for both ADMM and reference simulator. The ADMM and reference simulator optimizations are implemented using 16 computer cores. For small and middle-size network problems, reference simulator optimization is faster than ADMM. However, the computational time 2204 of reference simulator optimization exponentially increases with the number of wells (size of the network). In contrast, the computational time 2202 of ADMM optimization increases linearly with the number of wells (size of the network). As shown in FIG. 22, if the number of wells becomes larger than about 600, ADMM optimization becomes more efficient than the reference simulator. As the size of the network increases, the strength of the ADMM optimization is enhanced since more subnetwork problems can be solved simultaneously. In some embodiments, the ADMM optimization methods may effectively treat a significant amount of inequality constraints in the network systems by using the augmented Lagrangian method. The penalty term is added in the last term of the objective function (Equation (2)), which yields convergence without assumptions of strict convexity or finiteness of the function. In a conventional separable programming approach, such as sequential quadratic programming (SQP) and sequential linear programming (SLP), the inequality constraints are treated by using the active set method. It is an iterative strategy to deal with inequality constraints, and it can be computationally expensive when there is a significant amount of inequality constraints. The computational cost of the disclosed ADMM model can be further improved through better software engineering and by using more efficient optimization libraries.

TABLE 6

| | | |
|---|---|---|
| Number of wells | | |
| (size of the network) | ADMM | reference simulator |

| | | | | |
|---|---|---|---|---|
| 9 | 1.3 | [min] | 0.015 | [min] |
| 27 | 6.4 | [min] | 0.087 | [min] |
| 256 | 24.0 | [min] | 8.5 | [min] |
| 1024 | 78.0 | [min] | 163.0 | [min] |

### Field Application

In some embodiments, in the following example, the ADMM optimization methods are applied to a field case to validate the capability of the proposed ADMM method for actual field problems.

### Example 1

FIG. 23 illustrates a schematic representation of a production network 2300 in a field case, in accordance with certain embodiments. In particular, the production network 2300 includes a mature gas condensate field satellite with 43 wells that have very high gas-oil ratio. Though the pipeline has adequate capacity, new wells have been added to the network that share the same trunklines. The wells comingle production from multiple formations from a single wellbore and, as a result, the inflow performance curves are based on surface conditions based on wellhead pressure and surface rate measurements. Increasing water production in the wells over time diminishes the productivity of certain wells due to liquid loading and decreased gas production. The reservoir pressures and the separator pressure are given as boundary conditions. The disclosed ADMM network optimization method was used to solve for pressure and 3-phase fluxes. The simulation results are compared with a reference simulator that uses traditional nonlinear programming techniques. A multiphase inflow performance relationship (IPR), a deliverability equation based on tuning parameters (c and n) for gas reservoirs, and a Beggs and Brill model are used for pipe flow pressure calculations.

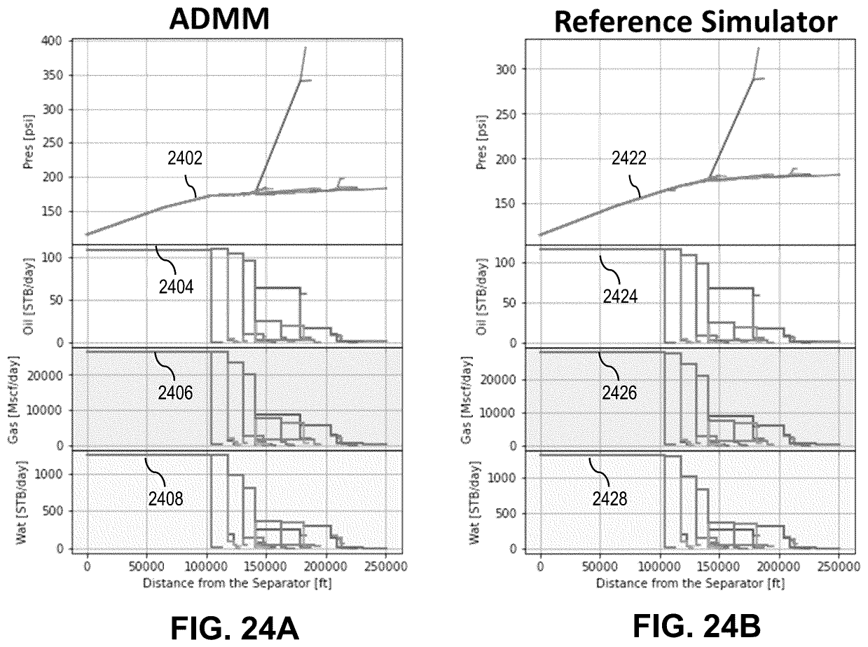

FIGS. 24A and 24B illustrate plots of calculated pressure and multiphase flux from ADMM and reference simulator for the field case, in accordance with certain embodiments. FIG. 24A shows the calculated node pressure 2402 and multiphase fluxes, such as oil rate 2404, gas rate 2406, and watercut 2408, from ADMM. FIG. 24A shows the calculated node pressure 2422 and multiphase fluxes, such as oil rate 2424, gas rate 2426, and watercut 2428, from reference simulator. The horizontal axis is the distance from the separator to each junction and reservoir node. As can be seen in FIGS. 24A and 24B, the smallest pressure is at the separator point, and it increases as it goes to each junction and reservoir node. The flux becomes maximum at the source link connected to the separator, and the flux decreases as the distance goes to upstream levels of the gathering system.

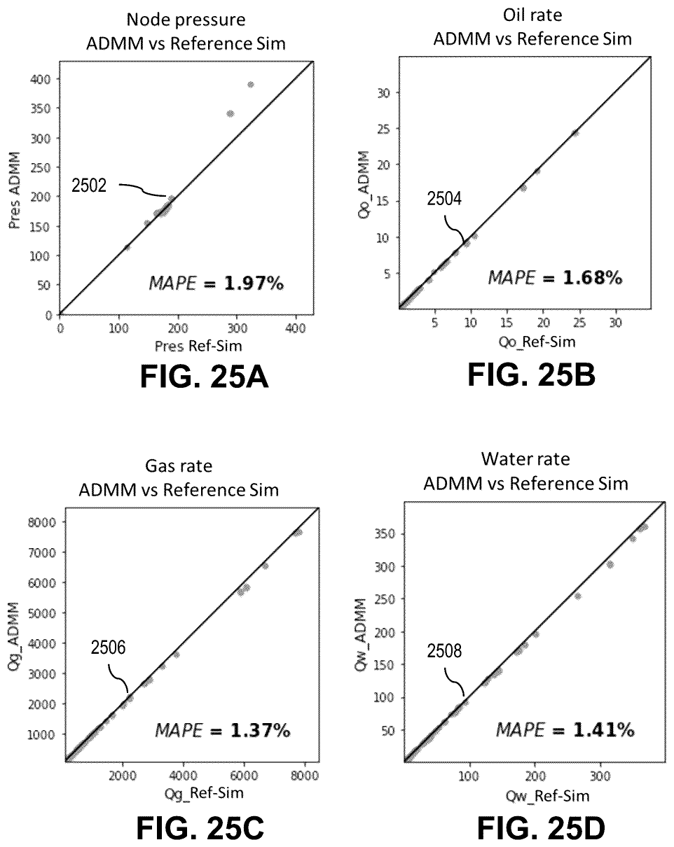

FIGS. 25A-25D illustrate plots comparing pressure and multiphase flux between ADMM and reference simulator for the field case, in accordance with certain embodiments. FIG. 25A shows the comparison of the calculated pressure 2502 for all nodes and links between ADMM and reference simulator with a 1.97% MAPE. FIG. 25B shows the comparison of the calculated oil rate 2504 for all nodes and links between ADMM and reference simulator with a 1.68% MAPE. FIG. 25C shows the comparison of the calculated gas rate 2506 for all nodes and links between ADMM and reference simulator with a 1.37% MAPE. FIG. 25D shows the comparison of the calculated gas rate 2508 for all nodes and links between ADMM and reference simulator with a 1.41% MAPE. The MAPE of the calculated pressure and multiphase fluxes are less than 2.0% between the ADMM and reference simulator. This indicates that ADMM method provides reasonable accuracy for pressure and multiphase flux calculation for the actual field problem.

### Methods for Modeling Pressure and Flux

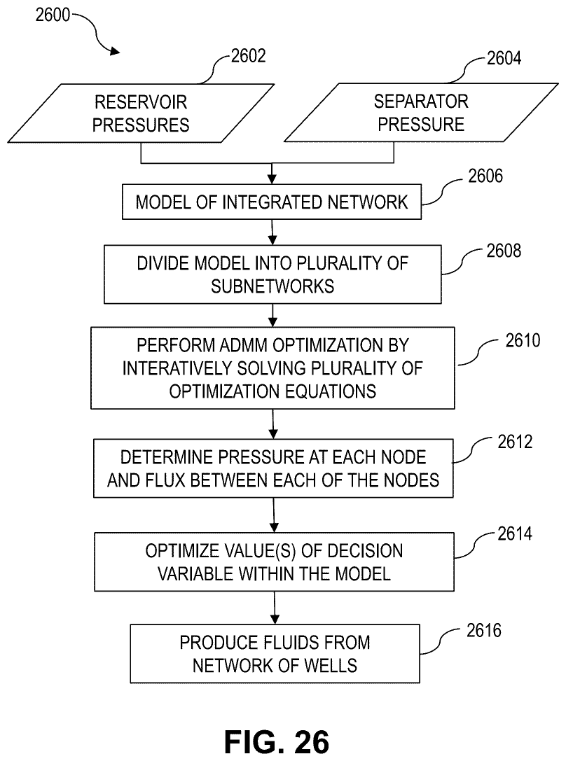

FIGS. 26-28 depict various methods in accordance with the present techniques. While the various blocks in FIGS. 26-28 are presented and described sequentially, some or all of the blocks may be executed in different orders, may be combined or omitted, and some or all of the blocks may be executed in parallel. Furthermore, the blocks may be performed actively or passively.

FIG. 26 illustrates a flow chart of an example method 2600 of modeling pressure and flux within an integrated network of multiple wells, in accordance with certain embodiments. In some embodiments, each of the multiple wells extends into a subterranean reservoir and being fluidly connected to the same separator, in accordance with one or more embodiments. At block 2602, the method 2600 includes measuring reservoir pressures at each well of the multiple wells. At block 2604, the method 2600 includes measuring a separator pressure at the separator. At block 2606, the method 2600 includes receiving or generating a model of the integrated network, the model including a node representing the separator, at least one node representing each well of the multiple wells, and pressure constraints at the separator and each well based on the measured separator pressure and reservoir pressures. In an embodiment, at block 2606 the method 2600 may include generating the model of the integrated network based on at least one additional constraint on production operations. At block 2608, the method 2600 includes dividing the model of the integrated network into a plurality of subnetworks.

At block 2610, the method 2600 includes performing an alternating direction method of multipliers (ADMM) optimization by iteratively solving a plurality of optimization equations. Each optimization equation corresponds to a different subnetwork of the plurality of subnetworks. As discussed above, the plurality of optimization equations may be determined using augmented Lagrangian method. In an embodiment, the method 2600 may include performing the ADMM optimization to maximize a flux at the node representing the separator. In an embodiment, the method 2600 may include iteratively solving a subset of optimization equations in the plurality of optimization equations in parallel using multiple processors. For example, the subset of optimization equations may correspond to subnetworks that are all at the same hierarchical depth in the model. In an embodiment, at block 2610 the method 2600 may include performing the ADMM optimization by iteratively solving the plurality of optimization equations until pressure and flux values in the model converge. In an embodiment, each optimization equation may incorporate a proxy model that correlates multiphase flow along a link of the model with pressure values.

At block 2612, the method 2600 includes determining a pressure at each node and a flux between each of the nodes in the model based on the optimization. For example, at block 2612 the method 2600 may include determining the pressures and fluxes in the model based on converged pressure and flux values from the optimization. Determining the flux between each of the nodes may include determining a multiphase flux between each of the nodes in the model based on the optimization. In an embodiment, at blocks 2610 and 2614, the method 2600 may include performing the ADMM optimization to optimize one or more values of a decision variable within the model. The decision variable may be present in at least one optimization equation and corresponding to at least one well in the model. The decision variable may include at least one variable selected from the group consisting of: choke size, artificial lift, downhole internal control valve (ICV) size, tubing size, pipeline size, pipeline design, tic-back analysis, pump/compressor size, pump/compressor location, pipeline leak detection, transportation of alternate energy forms, dynamic pipeline routing, pipeline emissions, steady-state flow assurance, and corrosion analysis. At block 2616, the method 2600 includes producing fluids from the network of multiple wells based, at least in part, on the determined pressures and fluxes in the model. In certain embodiments, at block 2616 the method 2600 may include producing fluids from the network of multiple wells based on the optimized one or more values of the decision variable.

Particular embodiments may repeat one or more steps of the method of FIG. 26, where appropriate. Although this disclosure describes and illustrates particular steps of the method of FIG. 26 as occurring in a particular order, this disclosure contemplates any suitable steps of the method of FIG. 26 occurring in any suitable order. Moreover, although this disclosure describes and illustrates an example method to perform the ADMM optimization methods for modeling pressure and flux within an integrated network of multiple wells, including the particular steps of the method of FIG. 26, this disclosure contemplates any suitable method, including any suitable steps, which may include all, some, or none of the steps of the method of FIG. 26, where appropriate. In some embodiments, although this disclosure describes and illustrates particular components, devices, or systems carrying out particular steps of the method of FIG. 26, this disclosure contemplates any suitable combination of any suitable components, devices, or systems carrying out any suitable steps of the method of FIG. 26.

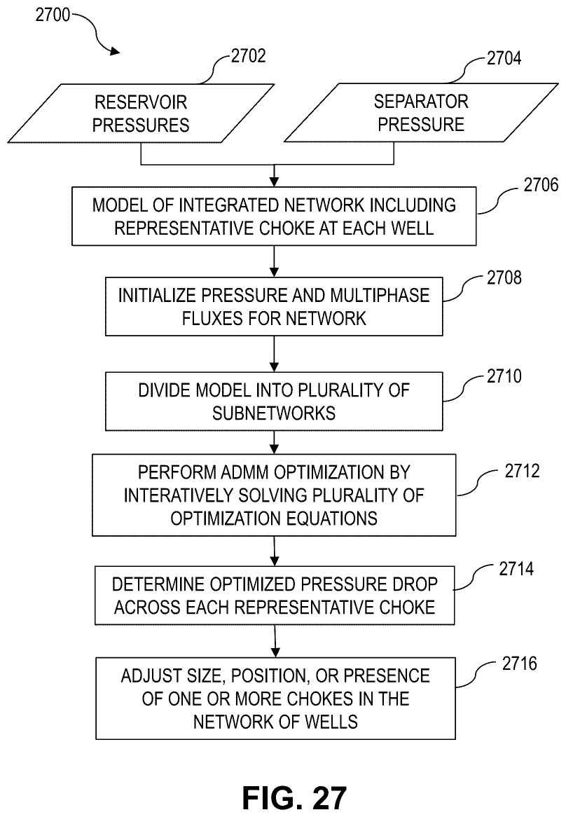

FIG. 27 illustrates a flow chart of an example method 2700 of modeling pressure and flux to perform a choke optimization in an integrated network of multiple wells, in accordance with certain embodiments. In some embodiments, each of the multiple wells extends into a subterranean reservoir and being fluidly connected to the same separator. At block 2702, the method 2700 includes measuring reservoir pressures at each well of the multiple wells. At block 2704, the method 2700 includes measuring a separator pressure at the separator. At block 2706, the method 2700 includes receiving or generating a model of the integrated network, the model including a node representing the separator, at least one node representing each well of the multiple wells, a representative choke at each well of the multiple wells, and pressure constraints at the separator and each well based on the measured separator pressure and reservoir pressures. At block 2708, the method 2700 may include determining an initial pressure value at each node and an initial flux value along each link between consecutive nodes in the model (i.e., initializing pressure and multiphase fluxes for the network). This may involve, for example, performing the ADMM optimization with zero pressure drop from the chokes in the model (e.g., as in block 2610 of the method 2600 of FIG. 26). At block 2710, the method 2700 includes dividing the model of the integrated network into a plurality of subnetworks.

At block 2710, the method 2700 includes performing an alternating direction method of multipliers (ADMM) optimization by iteratively solving a plurality of optimization equations, each optimization equation corresponding to a different subnetwork of the plurality of subnetworks. The optimization may be started using the initialized pressure and multiphase fluxes determined at block 2708. In an embodiment, block 2712 may include performing the ADMM optimization to maximize a flux at the node representing the separator. At block 2714, the method 2700 includes determining an optimized pressure drop across each representative choke in the model based on the optimization. At block 2716, the method 2700 includes adjusting a size, position, or presence of one or more chokes in the network of multiple wells based, at least in part, on the optimized pressure drops.

Particular embodiments may repeat one or more steps of the method of FIG. 27, where appropriate. Although this disclosure describes and illustrates particular steps of the method of FIG. 27 as occurring in a particular order, this disclosure contemplates any suitable steps of the method of FIG. 27 occurring in any suitable order. Moreover, although this disclosure describes and illustrates an example method to perform the ADMM optimization methods for modeling pressure and flux to perform a choke optimization in an integrated network of multiple wells, including the particular steps of the method of FIG. 27, this disclosure contemplates any suitable method, including any suitable steps, which may include all, some, or none of the steps of the method of FIG. 27, where appropriate. In some embodiments, although this disclosure describes and illustrates particular components, devices, or systems carrying out particular steps of the method of FIG. 27, this disclosure contemplates any suitable combination of any suitable components, devices, or systems carrying out any suitable steps of the method of FIG. 27.

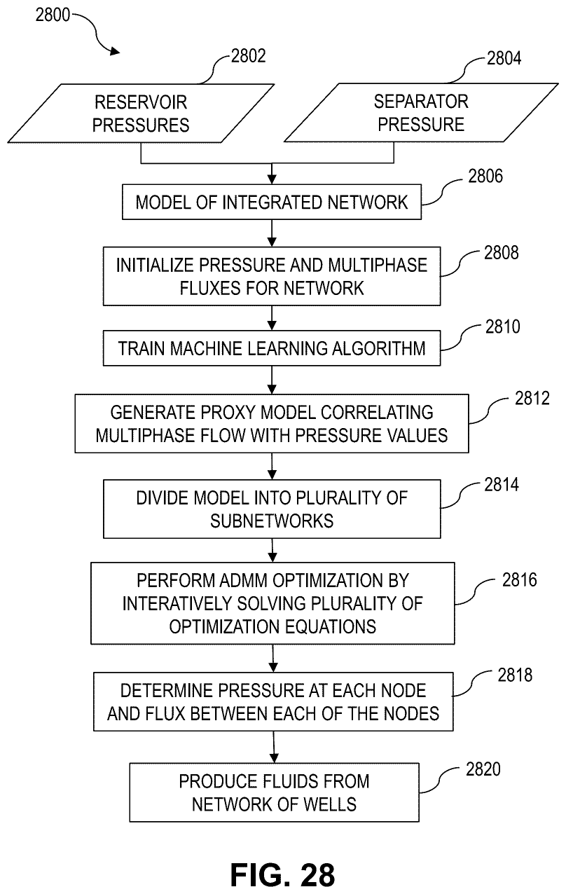

FIG. 28 illustrates a flow chart of an example method 2800 of modeling pressure and flux within an integrated network of multiple wells using a proxy model, in accordance with certain embodiments. In some embodiments, each of the multiple wells extends into a subterranean reservoir and being fluidly connected to the same separator. At block 2802, the method 2800 includes measuring reservoir pressures at each well of the multiple wells. At block 2804, the method 2800 includes measuring a separator pressure at the separator. At block 2806, the method 2800 includes receiving or generating a model of the integrated network, the model including a node representing the separator, at least one node representing each well of the multiple wells, and pressure constraints at the separator and each well based on the measured separator pressure and reservoir pressures. At block 2808, the method includes determining an initial pressure value (initialized pressure) at each node and an initial flux value (e.g., initialized multiphase flow) along each link between consecutive nodes in the model. At block 2810, the method 2800 includes training a machine learning algorithm based on the initial pressure and flux values. In an embodiment, this may include determining ranges of parameters for calculating multiphase flow based on the initial pressure and flux values, and training the machine learning algorithm based on the ranges of parameters. The parameters for calculating multi-phase flow may include, for example, liquid flux (Q_{liquid}), water cut (WCT), gas liquid ratio (GLR), and one side node pressure (e.g., P_{down} or Pᵤₚ). The machine learning algorithm may include a cubic regression, or any other desired machine learning algorithm as listed above. At block 2812, the method 2800 includes generating a proxy model that correlates multiphase flow along a link with pressure values using the machine learning algorithm.

At block 2814, the method 2800 includes dividing the model of the integrated network into a plurality of subnetworks. At block 2816, the method 2800 includes performing an alternating direction method of multipliers (ADMM) optimization by iteratively solving a plurality of optimization equations, each optimization equation corresponding to a different subnetwork of the plurality of subnetworks and incorporating the proxy model. At block 2818, the method 2800 includes determining a pressure at each node and a flux between each of the nodes in the model based on the optimization. At block 2820, the method 2800 includes producing fluids from the network of multiple wells based, at least in part, on the determined pressures and fluxes in the model.

Particular embodiments may repeat one or more steps of the method of FIG. 28, where appropriate. Although this disclosure describes and illustrates particular steps of the method of FIG. 28 as occurring in a particular order, this disclosure contemplates any suitable steps of the method of FIG. 28 occurring in any suitable order. Moreover, although this disclosure describes and illustrates an example method to perform the ADMM optimization methods for modeling pressure and flux within an integrated network of multiple wells using a proxy model, including the particular steps of the method of FIG. 28, this disclosure contemplates any suitable method, including any suitable steps, which may include all, some, or none of the steps of the method of FIG. 28, where appropriate. In some embodiments, although this disclosure describes and illustrates particular components, devices, or systems carrying out particular steps of the method of FIG. 28, this disclosure contemplates any suitable combination of any suitable components, devices, or systems carrying out any suitable steps of the method of FIG. 28.

### Hardware Implementation

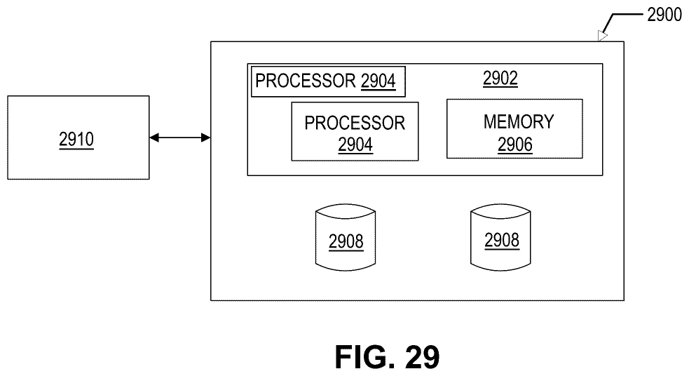

FIG. 29 illustrates a block diagram of an exemplary control unit 2900 in accordance with some embodiments of the present disclosure. In certain example embodiments, control unit 2900 may be configured to create and maintain one or more databases 2908 that include information concerning one or more network models. In certain example embodiments, control unit 2900 is configured to use information from database(s) 2908 to train one or many machine learning algorithms, including, but not limited to, artificial neural network, random forest, gradient boosting, support vector machine, or kernel density estimator. In some embodiments, control system 2902 may include one more processors, such as processors 2904. Processors 2904 may each include, for example, a microprocessor, microcontroller, digital signal processor (DSP), application specific integrated circuit (ASIC), or any other digital or analog circuitry configured to interpret and/or execute program instructions and/or process data. The multiple processors may be used to simultaneously solve different subsets of optimization equations in a plurality of optimization equations using the disclosed ADMM optimization(s). This allows the control unit 2900 to complete the ADMM optimization(s) faster than would be possible using other types of optimizations for modeling pressure and flux in a production network.

In some embodiments, processors 2904 may be communicatively coupled to a memory 2906. Processors 2904 may be configured to interpret and/or execute non-transitory program instructions and/or data stored in memory 2906. Program instructions or data may constitute portions of software for carrying out production forecasts, as described herein. Memory 2906 may include any system, device, or apparatus configured to hold and/or house one or more memory modules; for example, memory 2906 may include read-only memory, random access memory, solid state memory, or disk-based memory. Each memory module may include any system, device or apparatus configured to retain program instructions and/or data for a period of time (e.g., computer-readable non-transitory media).

Although control unit 2900 is illustrated as including two databases 2908, control unit 2900 may contain any suitable number of databases and machine learning algorithms. Control unit 2900 may be communicatively coupled to one or more displays 2910 such that information processed by control system 2902 may be conveyed to operators at or near the well or may be displayed at a location offsite.

Modifications, additions, or omissions may be made to FIG. 29 without departing from the scope of the present disclosure. For example, FIG. 29 shows a particular configuration of components for control unit 2900. However, any suitable configurations of components may be used. For example, components of control unit 2900 may be implemented either as physical or logical components. Furthermore, in some embodiments, functionality associated with components of control unit 2900 may be implemented in special purpose circuits or components. In other embodiments, functionality associated with components of control unit 2900 may be implemented in a general purpose circuit or components of a general purpose circuit. For example, components of control unit 2900 may be implemented by computer program instructions.

### CONCLUSION

A novel network optimization approach is developed using the Alternating Direction Method of Multipliers (ADMM). The ADMM framework can be used for network simulation to solve for pressure and flux of all nodes and links, and network optimization in which the additional choke pressure drops at wellheads are optimized to maximize the oil production rate of the gathering system. The proposed ADMM framework can accelerate large-scale gathering system optimization by solving the large network system in a distributed fashion. Additionally, the augmented Lagrangian method can effectively deal with a significant amount of inequality constraints, so that the large-scale network optimization can be accelerated further compared with benchmarks. The ADMM algorithm is applied to network simulation cases, which solve for the pressure and multiphase flux of all nodes and links. The simulation results were compared with a reference simulator, and reasonable agreement was obtained from the ADMM network simulation. Next, the ADMM framework is applied to network optimization cases, which optimize choke additional pressure drops for all wellheads to maximize the oil production of the gathering system. Although the optimized choke pressure drop solutions are different between ADMM and benchmark software, both methodologies provided similar performance of oil production improvement. The computational time of optimization by reference simulator increases exponentially with the size of the networks. In contrast, the computational time of ADMM optimization increases linearly with the size of the networks. When the size of the network becomes large enough (>600 wells), ADMM network optimization performs faster than the reference simulator. The ADMM optimization algorithm was applied to an actual gas condensate field case, and it provided reasonable accuracy in terms of pressure and multiphase flux calculation.

The ADMM network optimization algorithm has broad applicability and has the potential to solve several field use cases—such as surface choke optimization, artificial lift optimization, downhole ICV optimization, wellbore design (tubing size) analysis, pipeline sizing and design optimization, tie-back analysis, pump/compressor sizing and location optimization, model-based pipeline leak detection, transportation of alternate energy forms (e.g. geothermal, hydrogen and natural gas reservoirs), dynamic pipeline routing and route design optimization, pipeline emissions management, steady-state flow assurance and corrosion analysis etc. In future work, the efficiency of the ADMM framework may be further improved by tuning the code and using more efficient optimizers. Although the example provided consider only black oil flow model and isothermal conditions, more complex physics can be included in the disclosed ADMM framework.

Modifications, additions, or omissions may be made to the systems and apparatuses described herein without departing from the scope of the disclosure. The components of the systems and apparatuses may be integrated or separated. Moreover, the operations of the systems and apparatuses may be performed by more, fewer, or other components. Additionally, operations of the systems and apparatuses may be performed using any suitable logic comprising software, hardware, and/or other logic. As used in this document, “each” refers to each member of a set or each member of a subset of a set.

Modifications, additions, or omissions may be made to the methods described herein without departing from the scope of the invention. For example, the steps may be combined, modified, or deleted where appropriate, and additional steps may be added. Additionally, the steps may be performed in any suitable order without departing from the scope of the present disclosure.

Although the present invention has been described with several embodiments, a myriad of changes, variations, alterations, transformations, and modifications may be suggested to one skilled in the art, and it is intended that the present invention encompass such changes, variations, alterations, transformations, and modifications as fall within the scope of the appended claims. Therefore, the present invention is well adapted to attain the ends and advantages mentioned as well as those that are inherent therein. The particular embodiments disclosed above are illustrative only, as the present invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular illustrative embodiments disclosed above may be altered or modified and all such variations are considered within the scope and spirit of the present invention. Also, the terms in the claims have their plain, ordinary meaning unless otherwise explicitly and clearly defined by the patentee. The indefinite articles “a” or “an,” as used in the claims, are each defined herein to mean one or more than one of the element that it introduces.

A number of examples have been described. Nevertheless, it will be understood that various modifications can be made. Accordingly, other implementations are within the scope of the following claims.

What is claimed is:

1. A method of modeling pressure and flux within an integrated network of multiple wells, the multiple wells each extending into a subterranean reservoir and being fluidly connected to a same separator, the method comprising:
measuring reservoir pressures at each well of the multiple wells;
measuring a separator pressure at the separator;
receiving or generating a model of the integrated network, the model including a node representing the separator, at least one node representing each well of the multiple wells, and pressure constraints at the separator and each well based on the measured separator pressure and reservoir pressures;
dividing the model of the integrated network into a plurality of subnetworks;
performing an alternating direction method of multipliers (ADMM) optimization by iteratively solving a plurality of optimization equations, each optimization equation corresponding to a different subnetwork of the plurality of subnetworks;
determining a pressure at each node and a flux between each of the nodes in the model based on the optimization; and
producing fluids from the network of multiple wells based, at least in part, on the determined pressures and fluxes in the model.

2. The method of claim 1, further comprising performing the ADMM optimization to maximize a flux at the node representing the separator.

3. The method of claim 1, wherein the plurality of optimization equations are determined using augmented Lagrangian method.

4. The method of claim 1, further comprising iteratively solving a subset of optimization equations in the plurality of optimization equations in parallel using multiple processors.

5. The method of claim 4, wherein the subset of optimization equations correspond to subnetworks that are all at a same hierarchical depth in the model.

6. The method of claim 1, further comprising generating the model of the integrated network based on at least one additional constraint on production operations.

7. The method of claim 1, further comprising:
performing the ADMM optimization by iteratively solving the plurality of optimization equations until pressure and flux values in the model converge;
determining the pressure at each node and the flux between each of the nodes in the model based on the converged pressure and flux values.

8. The method of claim 1, further comprising determining a multiphase flux between each of the nodes in the model based on the optimization.

9. The method of claim 1, further comprising:
performing the ADMM optimization to optimize one or more values of a decision variable within the model, the decision variable being present in at least one optimization equation and corresponding to at least one well in the model; and
producing fluids from the network of multiple wells based on the optimized one or more values of the decision variable.

10. The method of claim 9, wherein the decision variable comprises at least one variable selected from the group consisting of: choke size, artificial lift, downhole internal control valve (ICV) size, tubing size, pipeline size, pipeline design, tie-back analysis, pump/compressor size, pump/compressor location, pipeline leak detection, transportation of alternate energy forms, dynamic pipeline routing, pipeline emissions, steady-state flow assurance, and corrosion analysis.

11. The method of claim 1, wherein each optimization equation incorporates a proxy model that correlates multi-phase flow along a link with pressure values.

12. A method of modeling pressure and flux within an integrated network of multiple wells, the multiple wells each extending into a subterranean reservoir and being fluidly connected to a same separator, the method comprising:
measuring reservoir pressures at each well of the multiple wells;
measuring a separator pressure at the separator;
receiving or generating a model of the integrated network, the model including a node representing the separator, at least one node representing each well of the multiple wells, a representative choke at each well of the multiple wells, and pressure constraints at the separator and each well based on the measured separator pressure and reservoir pressures;
determining an initial pressure value at each node and an initial flux value along each link between consecutive nodes in the model;
dividing the model of the integrated network into a plurality of subnetworks;
performing an alternating direction method of multipliers (ADMM) optimization by iteratively solving a plurality of optimization equations, each optimization equation corresponding to a different subnetwork of the plurality of subnetworks;
determining an optimized pressure drop across each representative choke in the model based on the optimization; and
adjusting a size, position, or presence of one or more chokes in the network of multiple wells based, at least in part, on the optimized pressure drops.

13. The method of claim 12, further comprising performing the ADMM optimization to maximize a flux at the node representing the separator.

14. A method of modeling pressure and flux within an integrated network of multiple wells, the multiple wells each extending into a subterranean reservoir and being fluidly connected to a same separator, the method comprising:
measuring reservoir pressures at each well of the multiple wells;
measuring a separator pressure at the separator;
receiving or generating a model of the integrated network, the model including a node representing the separator, at least one node representing each well of the multiple wells, and pressure constraints at the separator and each well based on the measured separator pressure and reservoir pressures;
determining an initial pressure value at each node and an initial flux value along each link between consecutive nodes in the model;
training a machine learning algorithm based on the initial pressure and flux values;
generating a proxy model that correlates multiphase flow along a link with pressure values using the machine learning algorithm;
dividing the model of the integrated network into a plurality of subnetworks;
performing an alternating direction method of multipliers (ADMM) optimization by iteratively solving a plurality of optimization equations, each optimization equation corresponding to a different subnetwork of the plurality of subnetworks and incorporating the proxy model;
determining a pressure at each node and a flux between each of the nodes in the model based on the optimization; and
producing fluids from the network of multiple wells based, at least in part, on the determined pressures and fluxes in the model.

15. The method of claim 14, further comprising:
determining ranges of parameters for calculating multiphase flow based on the initial pressure and flux values; and
training the machine learning algorithm based on the ranges of parameters.

16. The method of claim 15, wherein the parameters for calculating multi-phase flow comprise liquid flux (Q_{liquid}), water cut (WCT), gas liquid ratio (GLR), and one side node pressure.

17. The method of claim 15, wherein the machine learning algorithm is a regression type, a random forest type, a decision tree type, or a neural network type.

18. The method of claim 14, further comprising iteratively solving a subset of optimization equations in the plurality of optimization equations in parallel using multiple processors.

19. The method of claim 18, wherein the subset of optimization equations correspond to subnetworks that are all at a same hierarchical depth in the model.

20. The method of claim 14, further comprising generating the model of the integrated network based on at least one additional constraint on production operations.
